(19) United States
(12) Patent Application Publication
(10) Pub. No.: US 2011/0260288 A1
(43) Pub. Date: Oct. 27, 2011

(54) SEMICONDUCTOR DEVICE AND METHOD FOR MANUFACTURING THE SAME

(75) Inventors: Mitsunari Sukekawa, Tokyo (JP); Taizo Yasuda, Tokyo (JP)

(73) Assignee: Elpida Memory, Inc., Tokyo (JP)

(21) Appl. No.: 13/090,565

(22) Filed: Apr. 20, 2011

(30) Foreign Application Priority Data
Apr. 21, 2010 (JP) 2010-097830

(51) Int. Cl. H01L 29/02; H01L 23/48; H01L 21/28

(52) U.S. Cl. 257/532; 438/675; 257/774; 257/754; 257/E21.158; 257/E23.011; 257/E23.01; 257/E29.002

(57) ABSTRACT

Provided is a method for manufacturing a semiconductor device comprising: a process of forming a first trench 101 in insulating material layer 100 formed on a semiconductor substrate, wherein the first trench has an upper width W2 larger than an lower width W1, and is extended in a first direction; a process of forming embedded layer 102 within the first trench 101, wherein the embedded layer has a height lower than the top of the trench; a process of forming side-walls 103 to cover wall surfaces of the first trench 101 exposed on embedded layer 102; and a process of etching embedded layer 102 using side-wall 103 as a mask to separate the embedded layer in the first direction.

### BACKGROUND OF THE INVENTION

1. Field of the Invention

The present invention relates to a semiconductor device suitable for large-scale integrated circuits and a method for manufacturing a semiconductor device including a method for forming ultra-fine patterns.

2. Description of the Related Art

In the field of semiconductor devices, particularly semiconductor memory devices, trends for high integration and high miniaturization have been increasingly accelerated.

A method for forming fine patterns having fine contacts suitable for large-scale semiconductor devices, such as a method for forming contact holes by etching an insulating film between layers in a region where space patterns are crossed using a mask pattern having two line and space patterns which are crossed each other has been known, for example in JP 2008-124444 A.

When using such a technique, fine contact plugs are usually disposed at a constant pitch. Reasons for this are as follows: firstly, in case of forming a fine contact hole pattern, because a light interference technique is used to form stably a pattern in the vicinity of a resolution limit in a photo-lithography technology, a periodic pattern may be advantageously used. Secondly, in case of DRAM, it requires that the capability of memory cell capacitor should be maximized to maximize an amount of signal when reading memory information from the memory cell. Therefore, if memory cell capacitors are disposed such that spaces between adjacent cell capacitors have an equivalent distance, a close-packed placement may be elaborated, resulting in maximizing an occupying area per 1 bit. It will be advantageous to maximize the capability of memory cell capacitor. As such, contacts with memory cell capacitor electrodes, that is, the top surfaces of contact plugs are generally disposed at a constant pitch.

Meanwhile, in some cases, sources/drains of a selective MOS transistor which are connected to the lower side of contact plug may not be disposed at an equivalent distance due to a problem of layout, and thus there was a problem that their positions are dislocated.

Generally, since contact plugs are formed from contact openings patterned the surface of insulation film by an etching process, they are extended downwardly toward a semiconductor substrate through the contact openings. Therefore, to solve the problem of misalignment, a method of introducing an intermediate wiring layer is considered. However, in this case, the structure of device is complicated, resulting in lowering a yield. Therefore, such a method is not desirable.

Furthermore, when contacts with memory cell capacitor electrodes and contacts with sources/drains of MOS transistor are dislocated as viewed from the plane, if they are connected as they are, there was a problem that openings are formed downwardly through contact openings, and a contact area with the source/drain is significantly reduced, resulting in increasing contact electrical resistance. Moreover, there was a problem that a contact failure may be frequently generated due to such a misalignment.

### SUMMARY

According to the present invention, provided are a novel method for manufacturing a semiconductor device to form stably a pattern in the vicinity of a resolution limit of a photo-lithography technology and to solve a increase in contact electrical resistance and a contact failure due to a misalignment or a contact area reduction in structures such as contact plugs, as well as a semiconductor device having unique contact plugs formed by the same method.

That is, according to an embodiment of the present invention, provided is a method for manufacturing a semiconductor device comprising:

forming a first trench on a semiconductor substrate, wherein the first trench has an upper side-width larger than an lower side-width, and is extended in a first direction;

forming an embedded layer within the first trench, wherein the embedded layer has a height lower than the top of the trench;

forming side-walls to cover wall surfaces of the first trench exposed on the embedded layer; and

etching the embedded layer by using the side-walls as a mask to separate the embedded layer into two in the direction parallel to a first direction.

Further, according to another embodiment of the present invention, provided is a semiconductor device comprising an insulating material layer formed on a semiconductor substrate and a conductive material plug passing through the insulating material layer from its top side to its bottom side, wherein the center positions of the top and bottom surfaces of the conductive material plug are dislocated as viewed from the plane, and the conductive material plug have substantially no bump in at least one side on a line extended in a direction misalignment.

Further, according to another embodiment of the present invention, provided is a semiconductor device comprising a insulating material layer formed on a semiconductor substrate and a first and second plugs of conductive material passing through the insulating material layer from its top side to its bottom side, wherein a distance between the centers in the top surfaces of the first and second plugs of conductive material is broader than a distance between the centers in the bottom surfaces thereof.

According to an embodiment of the present invention, provided is a novel method for forming a pattern to form stably a fine structure as compared to the related art.

According to another embodiment of the present invention, provided is a contact plug formed through an insulation layer, wherein the center positions of the top and bottom surfaces of the contact plug are dislocated as viewed from the plane, that is, an axis (a center line connecting the centers of the top and bottom surfaces) is inclined, and the contact plug has approximately straight shape to ensure a reduction in electrical resistance and a margin for alignment.

### BRIEF DESCRIPTION OF THE DRAWINGS

The above features and advantages of the present invention will be more apparent from the following description of certain preferred embodiments taken in conjunction with the accompanying drawings, in which FIG. 1 is a view showing a method for the manufacture of a semiconductor device according to Example 1 of the present invention;

FIG. 2 is a view showing a method for the manufacture of a semiconductor device according to Example 1 of the present invention;

FIG. 3 is a view showing a method for the manufacture of a semiconductor device according to Example 1 of the present invention;

FIG. 4 is a view showing a method for the manufacture of a semiconductor device according to Example 1 of the present invention;

FIG. 5 is a view showing a method for the manufacture of a semiconductor device according to Example 1 of the present invention;

FIG. 6 is a view showing a method for the manufacture of a semiconductor device according to Example 1 of the present invention;

FIG. 7 is a view showing a method for the manufacture of a semiconductor device according to Example 1 of the present invention;

FIG. 8 is a view showing a method for the manufacture of a semiconductor device according to Example 1 of the present invention;

FIG. 9 is a view showing a method for the manufacture of a semiconductor device according to Example 1 of the present invention;

FIG. 10 is a view showing a method for the manufacture of a semiconductor device according to Example 1 of the present invention;

FIG. 11 is a view showing a method for the manufacture of a semiconductor device according to Example 1 of the present invention;

FIG. 12 is a view showing a method for the manufacture of a semiconductor device according to Example 1 of the present invention;

FIG. 13 is a view showing a method for the manufacture of a semiconductor device according to Example 1 of the present invention;

FIG. 14 is a view showing a method for the manufacture of a semiconductor device according to Example 1 of the present invention;

FIG. 15 is a view showing a method for the manufacture of a semiconductor device according to Example 1 of the present invention;

FIG. 16 is a view showing a method for the manufacture of a semiconductor device according to Example 1 of the present invention;

FIG. 17 is a view showing a method for the manufacture of a semiconductor device according to Example 1 of the present invention;

FIG. 18 is a view showing a method for the manufacture of a semiconductor device according to Example 1 of the present invention;

FIG. 19 is a view showing a method for the manufacture of a semiconductor device according to Example 1 of the present invention;

FIG. 20 is a view showing a method for the manufacture of a semiconductor device according to Example 1 of the present invention;

FIG. 21 is a view showing a method for the manufacture of a semiconductor device according to Example 1 of the present invention;

FIG. 22 is a view showing a method for the manufacture of a semiconductor device according to Example 1 of the present invention;

FIG. 23 is a view showing a method for the manufacture of a semiconductor device according to Example 1 of the present invention;

FIG. 24 is a view showing a method for the manufacture of a semiconductor device according to Example 1 of the present invention;

FIG. 25 is a view showing a method for the manufacture of a semiconductor device according to Example 1 of the present invention;

FIG. 26 is a view showing a method for the manufacture of a semiconductor device according to Example 2 of the present invention;

FIG. 27 is a view showing a method for the manufacture of a semiconductor device according to Example 3 of the present invention;

FIG. 28 is a view showing a method for the manufacture of a semiconductor device according to Example 3 of the present invention;

FIG. 29 is a view showing a method for the manufacture of a semiconductor device according to Example 3 of the present invention;

FIG. 30 is a view showing a method for the manufacture of a semiconductor device according to Example 3 of the present invention;

FIG. 31 is a view showing a method for the manufacture of a semiconductor device according to Example 3 of the present invention;

FIG. 32 is a view showing a method for the manufacture of a semiconductor device according to Example 3 of the present invention;

FIG. 33 is a process cross-section view showing a method for the manufacture of a semiconductor device according to an embodiment of the present invention;

FIG. 34 is a conceptual view showing a contact plug according to an embodiment of the present invention; in FIG. 34(a)˜(b), figures in the left side are conceptual cross-section views, and figures in the right side are conceptual plane views;

FIG. 35(a) is a conceptual view showing a pair of contact plugs according to another embodiment of the present invention, and FIG. 35(b) shows a constant top pitch obtained by co-installation of a plurality of the plug pairs;

FIG. 36 is a view showing a conventional metal contact plug; FIG. 36(A) shows a cross-section along the line Y-Y′ of FIG. 36(C) that is a plane view; and FIG. 36(B) shows a cross-section along the line X-X′ of FIG. 36(C);

FIG. 37 is a view showing a conventional contact plug having a hybrid structure; FIG. 37(A) shows a cross-section along the line Y-Y′ of FIG. 37(C) that is a plane view; and FIG. 37(B) shows a cross-section along the line X-X′ of FIG. 37(C);

FIG. 38 is a view showing a contact plug having a hybrid structure according to Example 4 of the present invention; FIG. 38(A) shows a cross-section along the line Y1-Y1′ of FIG. 38(C) that is a plane view; and FIG. 38(B) shows a cross-section along the line X1-X1′ of FIG. 38(C);

FIG. 39 is a view showing a method for the manufacture of a semiconductor device according to Example 4 of the present invention;

FIG. 40 is a view showing a method for the manufacture of a semiconductor device according to Example 4 of the present invention;

FIG. 41 is a view showing a method for the manufacture of a semiconductor device according to Example 4 of the present invention;

FIG. 42 is a view showing a method for the manufacture of a semiconductor device according to Example 4 of the present invention; and

FIG. 43 is a process cross-section view showing a method for the manufacture of a semiconductor device according to another example of an embodiment of the present invention.

### DETAILED DESCRIPTION OF THE PREFERRED EMBODIMENTS

The invention will be now described herein with reference to exemplary embodiments. Those skilled in the art will recognize that many alternative embodiments can be accomplished using the teachings of the present invention and that the invention is not limited to the embodiments illustrated for explanatory purpose.

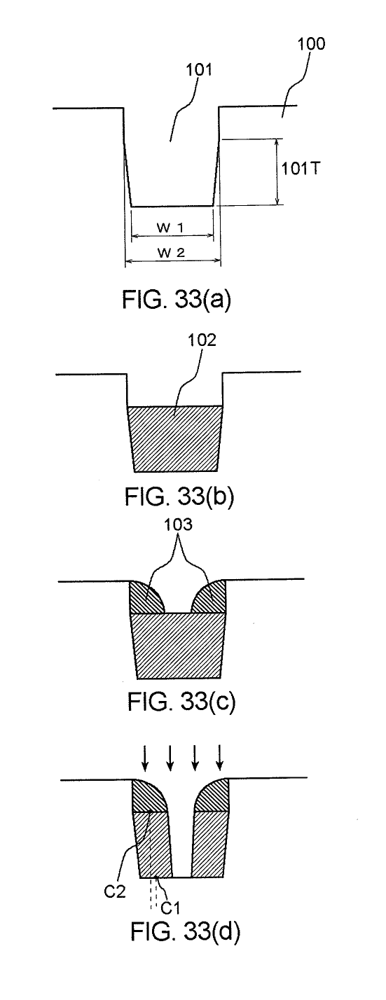

FIG. 33 is a process cross-section view showing a method for the manufacture of a semiconductor device according to an embodiment of the present invention.

First, as shown in FIG. 33(a), a first trench 101 is formed in insulating material layer 100 formed on a semiconductor substrate (not shown), wherein the first trench 101 is extended in a first direction. In case of the first trench 101, the top width W1 is broader than the bottom width W2. In this example, taper portion 101T is provided in the vicinity of the bottom side of trench. The shape of cross-section in the direction orthogonal to the first direction of the first trench is not limited to this example, and a taper portion where the entire side of trench is inclined may be formed, or a shape where its width is widened in step-wise shape may be formed. When using a usual dry etching process, the shape of cross-section of the first trench indicated is formed on a wall surface of which the left and right sides are symmetric, but one side of wall surface may be a perpendicular shape and the other side may be a taper-like or step-like shape, or the left and right sides of wall surface may be asymmetric. It is desirable a shape of which the left and right sides are symmetric and having no bump. This shape allows an easy processing procedure. Also, when a separated embedded layer forms a conductive material, particularly a contact plug, in terms of an electrical property of the formed contact plug, a symmetric shape having no bump is desirable.

Next, as shown in FIG. 33(b), embedded layer 102 is formed in the first trench, wherein the height of embedded layer 102 is lower than the top of trench. Embedded layer 102 is primarily made of conductive materials. For example, a layer having a desired thickness is formed using a material such as polysilicon, and the formed layer is subjected to an etch-back process, thereby forming the embedded layer of which the top surface is positioned at a position lower than the top of trench.

Next, as shown in FIG. 33(c), side-wall 103 is formed to cover a wall surface of the first trench 101 exposed on embedded layer 102. Preferably, side-wall 103 may be made of a material having an different etching property from embedded layer 102. If embedded layer 102 is made of a conductive material, side-wall 103 is primarily made of an insulating material. In this case, side-wall 103 is formed from a insulating material layer formed with a desired thickness by an etch-back process. Also, side-wall 103 may be made of a different conductive material from embedded layer 102.

Finally, as shown in FIG. 33(d), embedded layer 102 is etched using side-wall 103 as a mask to separate the embedded layer into the left and right sides (in the direction parallel to a first direction). Thereby, in at least one side of the separated embedded layer, as viewed from the plane, the center C1 in cross-section of its lower side and the center C2 in cross-section of its upper side are dislocated. Also, the etched and separated surface is formed as a shape having no bump.

According to this embodiment, by forming the embedded layer in the bottom side of the first trench, and etching the embedded layer using the side wall covering the side wall of trench exposed on the embedded layer as a hard mask, for both of the wide and space of a pattern, a pattern having any size below a resolution limit of a photo-lithography technology may be easily formed. Also, since the pattern is formed by etching the embedded layer formed in the bottom side of trench, any shape in the longitudinal direction (depth direction) of pattern may be also obtained by selecting properly an etching condition for forming the trench and controlling properly the widths of the bottom side and opening of trench.

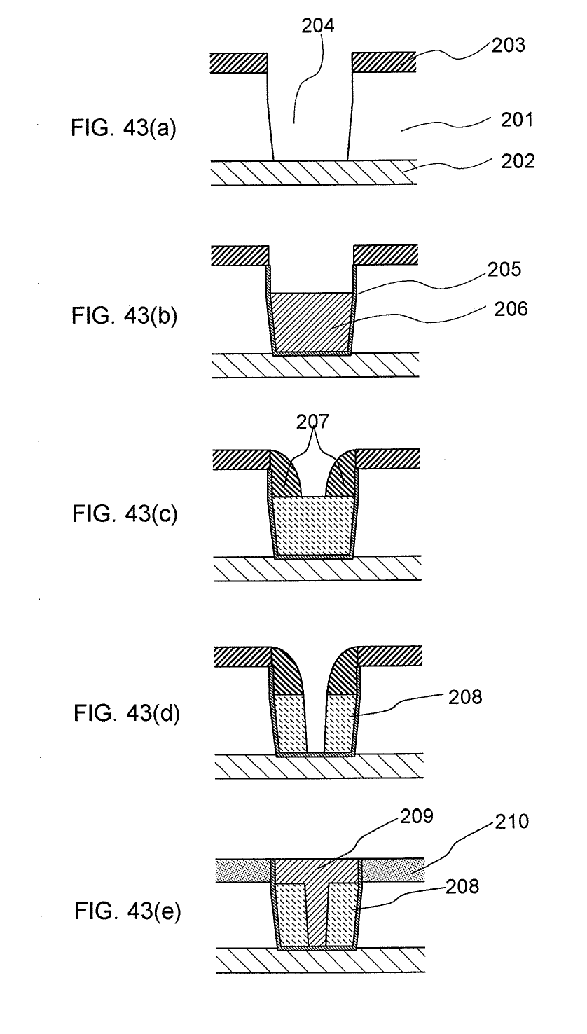

FIG. 43(a)-(e) show main processes in another example for producing gate electrodes on a side of silicon pillar formed with a trench in a silicon substrate by applying the present embodiment.

First, as shown in FIG. 43(a), mask SiN film 203 is formed on P-type silicon substrate 201 including embedded N-type impurity diffusion layer 202 and patterned to form an opening extended in a first direction. Then, P-type silicon substrate 201 is processed using thus patterned mask SiN film 203 as a mask to form trench 204, which is extending to the first direction.

Next, as shown in FIG. 43(b), P-type silicon substrate 201 is subjected to thermal oxidation to form gate insulating layer 205 on inner wall of trench 204. Polysilicon film is deposited on the substrate and etched back to form embedded layer 206.

On embedded layer 206, side-walls 207 made of SiN film are formed (FIG. 43(c)), and then embedded layer 206 is separated using side-wall 207 as a mask to form gate electrodes 208 on both wall of trench 204 (FIG. 43(d)). Finally, SiN films (mask SiN film 203 and side-walls 207) are removed. Embedded insulating layer 209 is embedded in trench 204 and then N-type impurity diffusion layers 210 are formed on the surface areas of P-type silicon substrate 201 (silicon pillars provided on both side of trench 204). According to these processes, a structure shown in FIG. 43(e) is completed.

Furthermore, to apply this embodiment to a process of forming a contact plug, the embedded layer which is formed as a line shape should be separated in the direction (a second direction) intersecting with the first direction within the first trench.

As an approach used for such separation, there are the following two approaches: a first approach is to separate the embedded layer from its top side using a mask material extended in the second direction. To this end, the following methods may be used: a method of separating the embedded layer into the left and right sides as shown in FIG. 33(d), and forming a mask material extended in the second direction to separate each side wall in the second direction; or a method of forming the side wall as shown in FIG. 33(c), forming a mask material extended in the second direction to separate the side wall in the second direction, removing the mask material, and separating the embedded layer into the first and second directions using the remaining side wall as a mask.

The other approach is a method of providing a compartment portion for separating the first trench in the second direction in the first trench, and forming the embedded layer within the first trench having the compartment portion, thereby separating the embedded layer in the second direction from the bottom of trench by the compartment portion. In this case, the top surface of compartment portion should be positioned at a position lower than the top of the first trench. Also, the top surface of compartment portion should not be projected from the embedded layer when forming the side wall. If the compartment portion is projected from the top surface of embedded layer, since the side wall is also formed on the wall surface of compartment portion, and it is not separated into the left and right sides, the top surface of compartment portion may be positioned at the same height as the surface of embedded layer, or the embedded layer may be formed to cover the top surface of compartment portion. In case that the height of the top surface of compartment portion is the same as the height of the surface of embedded layer, by separating in the first direction using the side wall as a mask, the embedded layer which is also separated in the second direction is formed. In case that the embedded layer is formed to cover the top surface of compartment portion, after separating the embedded layer in the first direction, both of the embedded layer and the side wall are subjected to an etch-back process until the surface of compartment portion below the side wall is exposed, or the embedded layer which is also separating in the second direction (contact plug) is formed on the bottom of the first trench by smoothing the entire material including an insulating material from which the first trench is formed by a method such as CMP. In case of the compartment portion, a protrusion extended in the second direction may be formed prior to the formation of the insulating material forming the first trench, and the protrusion may be exposed within the trench when forming the first trench. Further, when the compartment portion is formed such that the width of trench is separated from one side to the center portion, not separating the entire width, one side of embedded layer (conductive material) separated in the first direction is also separated in the second direction, and it may be used as a contact plug; the other side which is not separated in the second direction may be used as wiring extended in the first direction. As such, by forming a pattern by separating the embedded layer made of a conductive material embedded within the first trench into the first and second directions, a contact plug of which the axis (center line) is inclined and having an nearly straight shape may be obtained. The slope may be adjusted and controlled by selecting an etching condition for forming the trench. By using the contact plug having the inclined axis, since two nodes which are dislocated as viewed from the plane may be connected in an nearly straight shape, both of the top and bottom sides of contact plug may be positioned properly with respect to the position of each of two nodes, a sufficient contact area may be ensured, a sufficient margin for misalignment may be ensured, and an electrical resistance may be effectively reduced.

For the formation of mask material or protrusion extended in the second direction, a photo-lithography process should be added, however, in case of the latter protrusion, since component of semiconductor device is applied, it is not necessary to add a photo-lithography process for the purpose of the second direction-partition. Therefore, the latter protrusion is desirable. A method for forming the latter protrusion will be described in the following Example with reference to concrete examples.

As such, according to the present invention, by separating the embedded layer embedded within the trench into two portions in the first direction where the trench is extended, a width smaller than the half of trench-width may be obtained. Further, by separating the embedded layer in the second direction intersecting with the first direction, a more elaborate processing is allowed as compared to using a mask pattern having two line and space patterns which are crossed in the related art. Alternatively, by widening the width of the first trench, a processing allowance (margin) may be improved when the same size contact plug is formed. Further, by widening the opening-width of trench than the bottom-width of trench, it is possible to dislocate the centers in cross-sections of the top and bottom sides in the plane orthogonal to the first direction, as viewed from the plane, and thus a contact plug of which the top side-pitch is different from the bottom side-pitch may be formed.

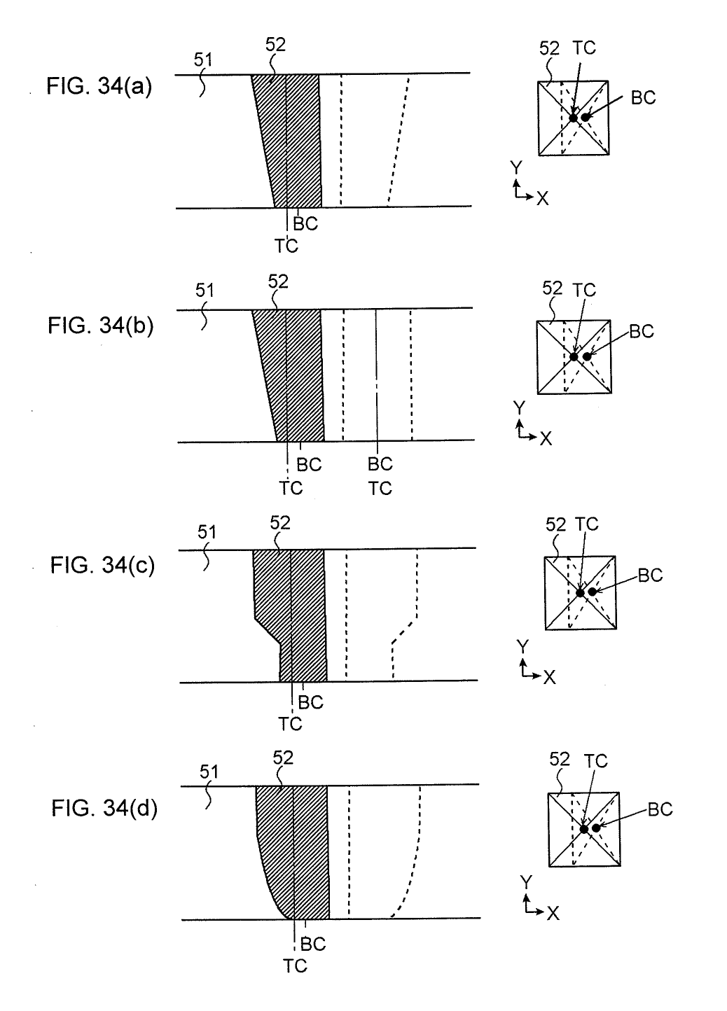

Next, a contact plug according to the present invention will be described. FIG. 34 shows conceptually a contact plug according to an embodiment of the present invention. The left side of FIG. 34 is a conceptual cross-section view, and the right side is a conceptual view as viewed from the plane. Further, one side plug represented by solid lines is primarily described herein, but broken lines shown in the cross-section of the left figure shows the other side plug formed according to the present invention.

Herein, FIG. 34(a) shows the case that a contact plug is formed in the first trench having the wall surface of which the left and right sides symmetric and a taper-like portion where the portion is widened from its bottom side toward its top side; FIG. 34(b) shows the case that a contact plug is formed in the first trench having the wall surface of which the left and right sides is asymmetric, wherein one wall surface has a taper-like portion, and the other wall surface has a nearly perpendicular shape; FIG. 34(c) shows the case that a contact plug is formed in the first trench having the wall surface of which the left and right sides is symmetric, wherein the wall surface is widened in step-wise shape from its bottom side toward its top side; and FIG. 34(d) shows the case that a contact plug is formed in the first trench having the wall surface of which the left and right sides is symmetric, wherein the wall surface is widened in curve-wise shape from its bottom side toward its top side

In FIG. 34, contact plug 52 is passed through insulation layer 51, the top and bottom surfaces of contact plug 52 has approximately same width in Y-direction (the first direction), the top surface-center TC and the bottom surface-center BC are dislocated in X-direction (the second direction), as viewed from the plane. To the contrary, in case of the other side contact plug represented by broken lines in FIG. 34(b), the top surface-center TC is nearly conformed with the bottom surface-center BC. In this example, although the first direction is orthogonal to the second direction, as long as the first direction and the second direction is crossed, the horizontal cross-section of contact plug may be a parallelogram-like shape other than the rectangular shape as shown in FIG. 34. In either case, since at least one side on the line extended in the misalignment direction of centers of contact plug 52 is formed by an etching process, a substantial bump does not show. Further, the top and bottom surfaces of contact plug 52 have an approximately rectangular shape. In addition, the top surface of contact plug represented by solid lines in FIG. 34(a) to FIG. 34(b) has larger area than that of the bottom surface, thereby improving an electrical resistance to electrodes formed on the top side and an alignment margin.

A self-aligned contact (SAC) is a fine contact technology. By using SAC technology, in case that a base conductive layer, for example a gate electrode layer within a contact opening area is exist, by covering the top surface and side of the conductive layer by a layer having a etching rate lower than the etching rate of contact opening, a contact opening may be formed while ensuring an insulating property. As such, when forming the contact plug by embedding a conductive material within the contact hole after the contact hole is formed, the center positions in the top and bottom surfaces of contact plug may be dislocated as viewed from the plane. In case of SAC technology, this technology is applied when a base conductive layer is exist in the side-direction of contact hole area, and all narrow distances are exposed in a wide opening by combining openings above a resolution limit of a photo-lithography technology at a distance narrower than the resolution limit by forming a layer having lower etching rate on side of conductive layer. Therefore, if the top surface-center and the bottom surface-center are dislocated, a bump shows at both of sides on the line extended in the misalignment direction. To the contrary, since the contact plug according to the present invention is formed as the separated state within the first trench by an etching process, at least separated side of contact plug corresponding to a first side on the line extended in the misalignment direction has no substantial bump except for small concaves and convexes which are generated due to a variation in etching rate, and has smooth surface. Further, in case of a contact plug formed by SAC technology, a portion of contact hole area in an insulation layer may fail to contribute to electrical conduction. However, in the present invention, because the entire opening area contributes to electrical conduction, an electrical resistance may be advantageously-reduced.

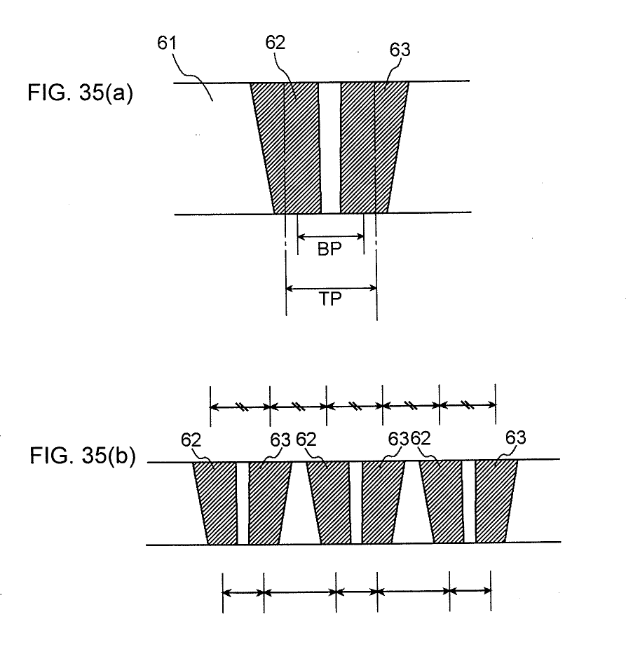

FIG. 35 shows conceptually a contact plug according to another embodiment of the present invention. As described in FIG. 33, in case of the contact plug formed according to the present invention, adjacent two contact plugs through insulation layer 61 are disposed in pair-wise shape. As shown in FIG. 35(a), the distance TP between the top surface-centers of adjacent two contact plugs (the left side of figure is referred to as a first contact plug 62, and the right side is referred to as a second contact plug 63) is larger than the distance BP between the bottom surface-centers. As shown in FIG. 35(b), by co-installing a plurality of plug pairs of the first contact plug 62 and the second contact plug 63, when the pitches in the bottom surface are not even, the pitches in the top surface may have a nearly equivalent distance.

For the co-installation of a plurality of plug pairs, a plurality of the first trench may be co-installed at a desired distance. In this case, trenches are formed such that the underlying conductors which are connected to the first and second contact plugs, such as two diffusion layers isolated from each other of adjacent transistors and underlying contact plugs are exposed in the bottom surface of trench, as described in the following Example. Also, a taper-like portion is formed such that the wall surface is widened from the bottom-center of trench, and preferably the left and right sides is symmetric. That is, a repetitive structure of valley, ridge, valley, ridge . . . is formed within a compartment, and the cross-section of this structure has an insulating material fin of a nearly trapezoidal shape. The ends of contact plug-forming area may be terminated at either of ridge or valley, and also a dummy plug not connected to the underlying conductor may be formed at outer side of contact plug at the ends. Further, if the ends of contact plug-forming area are terminated at a valley, the trench-width at the longitudinal ends is widened than other trench-width, and the aforementioned compartment portion within the trench is formed up to the center of the longitudinal ends, separated wiring may be formed simultaneously from the contact plug-forming area, as described above.

For the formation of contact plug, the embedded layer of conductive material being become a contact plug is separated in the first direction within the first trench. At the same time, this embedded layer should be also separated in the second direction intersecting with the first direction, as described above. If the embedded layer is partitioned from the lower side by the compartment portion provided within the trench, the side in the first direction of the contact plug has a shape reflecting the wall surface-shape of the compartment portion. Therefore, if the side of protrusion being become the compartment portion has a taper-like portion, the structure where the bottom side-width is narrowed in Y-direction as viewed from the plane shown in the right side of each figure may be also obtained.

Further, as shown in FIG. 35(b), to form the top side-pitches at a nearly equivalent distance, by controlling the width extension from the bottom side toward the top side of the first trench, particularly the taper angle of the inside wall of the first trench (angle as viewed from the top side relative to the direction perpendicular to the substrate) using a proper etching method for forming the first trench, the extent that the center positions in the top and bottom surfaces of the contact plug are dislocated may be adjusted. Meanwhile, to form the contact plug of which the top surface-area is larger than the bottom surface-area, the taper angle of the inside wall of the first trench and the taper angle of etching surface when etching and separating the embedded layer should be adjusted. Further, if the taper angles of the inside walls of the first trenches are the same, the extent of misalignment may be adjusted by adjusting the height of contact plug.

Now, examples according to the present invention will be described in detail with reference to the accompanying drawings. In the following Example, although a method for manufacturing a cell contact plug in a memory cell is described, the present invention is not limited to these examples, and may be applied to either of the case that the pitches are different in the top and bottom of contact plug, or the case that a contact plug should be formed at a fine pitch.

### Example 1

With respect to FIGS. 1 to 25, a method for the manufacture according to Example 1 of the present invention will be described.

X-direction and Y-direction that is orthogonal to X-direction in a plane parallel to a semiconductor substrate is defined as shown in FIG. 1(C). Likewise, as shown in FIG. 1(C), α-direction is defined as a direction where an element-forming area of a memory cell is extended, and β-direction is defined as direction that is orthogonal to a-direction. Also, Z-direction is defined as a direction that is perpendicular to the semiconductor substrate. Hereinafter, Y-direction is referred to as a first direction, and X-direction is referred to as a second direction. Likewise, α-direction is referred to as a third direction, and β-direction is referred to as a forth direction.

With respect to FIGS. 1, 4, 6, 7 to 15, 17, 19, 20 to 22 and 24, sub figures represented by (C) are top views corresponding to each process.

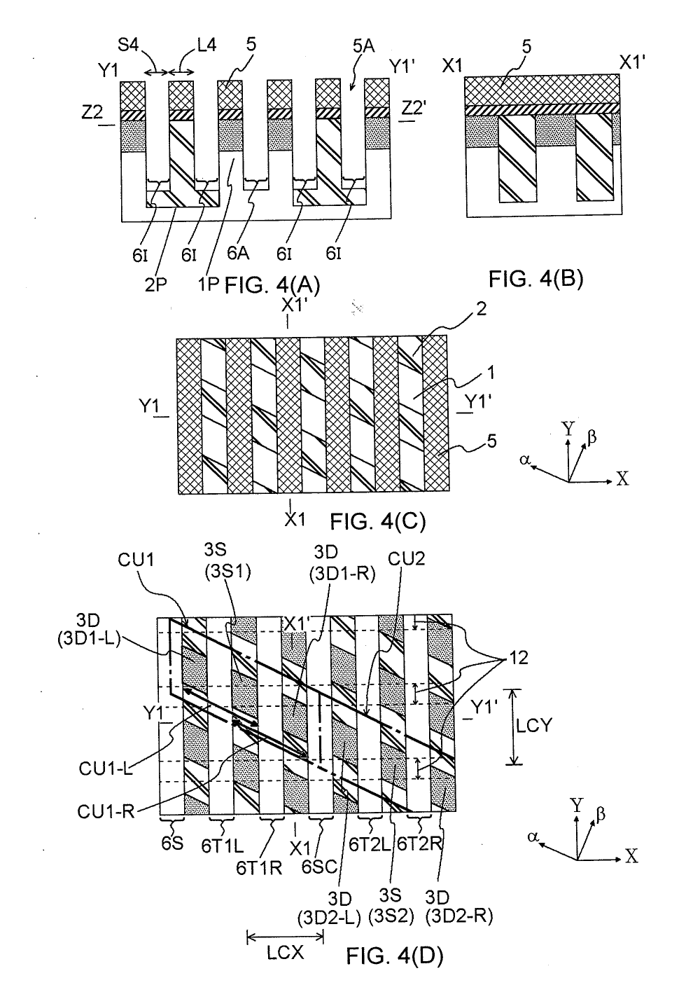

FIG. 4(D) is a cross-section view cut along the line Z2-Z2′ of FIG. 4(A), in which the cross-section is parallel to the semiconductor substrate.

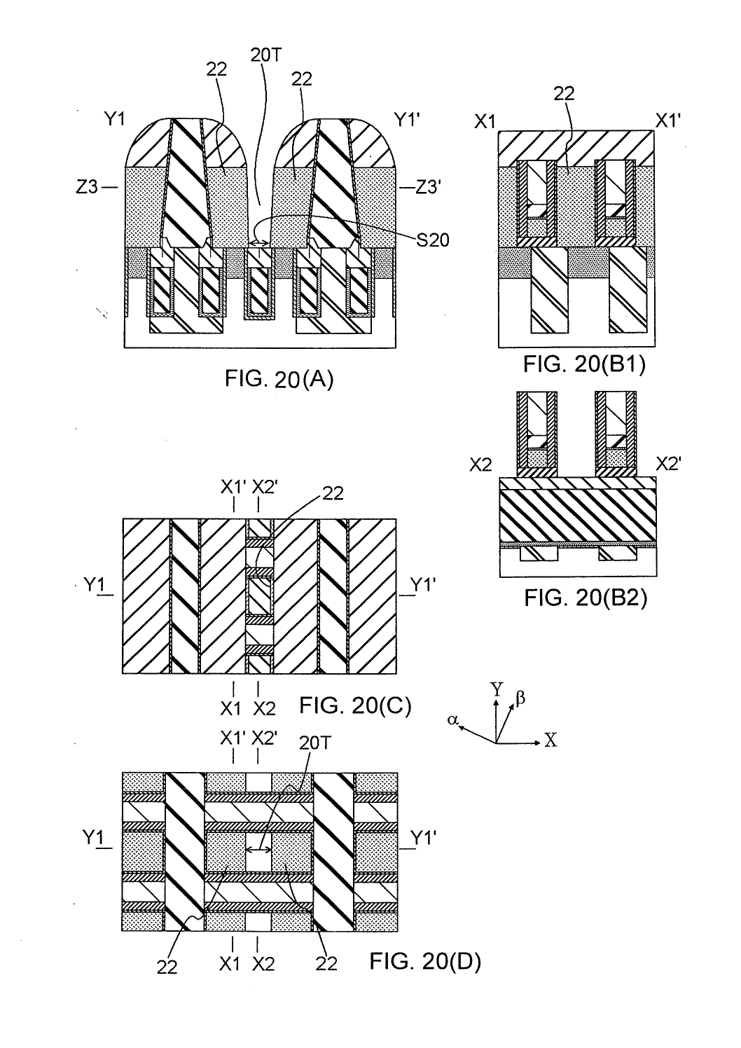

FIG. 20(D) is a cross-section view cut along the line Z3-Z3′ of FIG. 20(A), in which the cross-section is parallel to the semiconductor substrate.

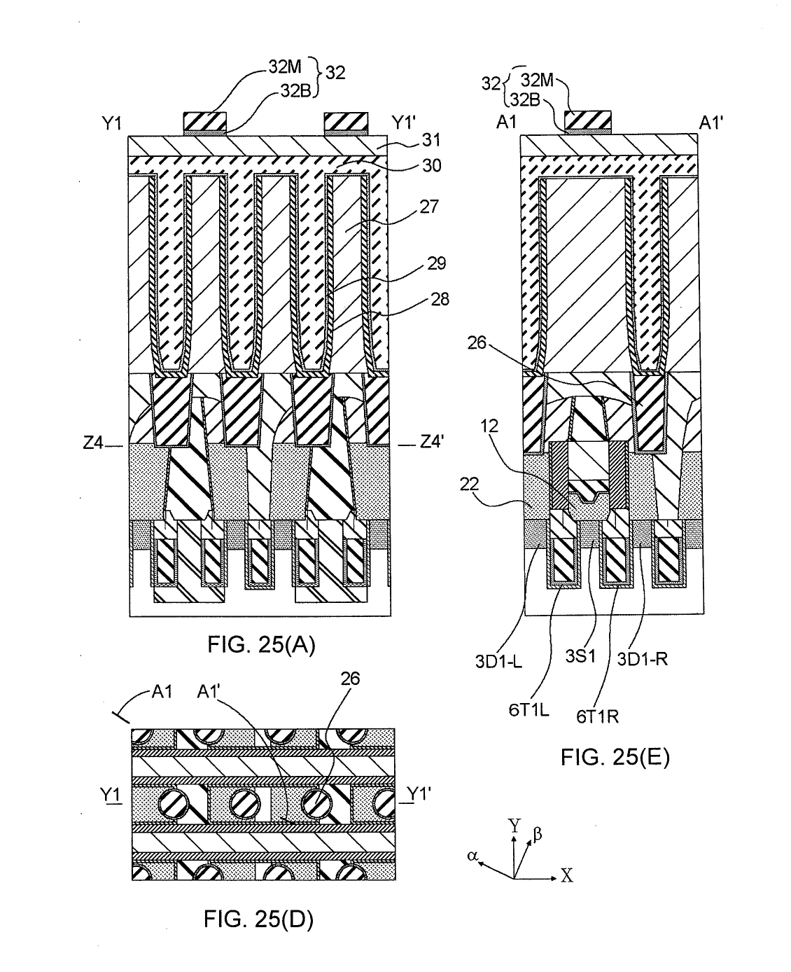

FIG. 25(D) is a cross-section view cut along the line Z4-Z4′ of FIG. 25(A), in which the cross-section is parallel to the semiconductor substrate.

With respect to FIGS. 1 to 25, sub figure (A) or (A1) is a cross-section view cut along the line Y1-Y1′ according to Y-direction shown in sub figure (C) or (D) of each figure, in which the cross-section is parallel to the semiconductor substrate. Likewise, sub figure (B) or (B1) of each figure is a cross-section view cut along the line X1-X1′ according to X-direction shown in sub figure (C) or (D) of each figure, in which the cross-section is parallel to the semiconductor substrate; and sub figure (B2) is a cross-section view cut along the line X2-X2′ according to X-direction shown in sub figure (C) or (D), in which the cross-section is parallel to the semiconductor substrate.

Also, FIG. 25(E) is a cross-section view cut along the line A1-A1′ according to A-direction shown in FIG. 25(D), in which the cross-section is parallel to the semiconductor substrate.

<Process of FIG. 1>

Element-isolating areas I comprising element isolation film 2 is formed on semiconductor substrate 1. A silicon substrate may be used as semiconductor substrate 1, and a silicon oxide film may be used as element isolation film 2. Element-forming areas A are formed on semiconductor substrate 1, which are compartmented by element-isolating areas I. Element-forming areas A are extended in α-direction that is inclined to X-direction on the plane, and disposed repeatedly in β-direction at a desired distance. In this Example, P-type semiconductor substrate is used.

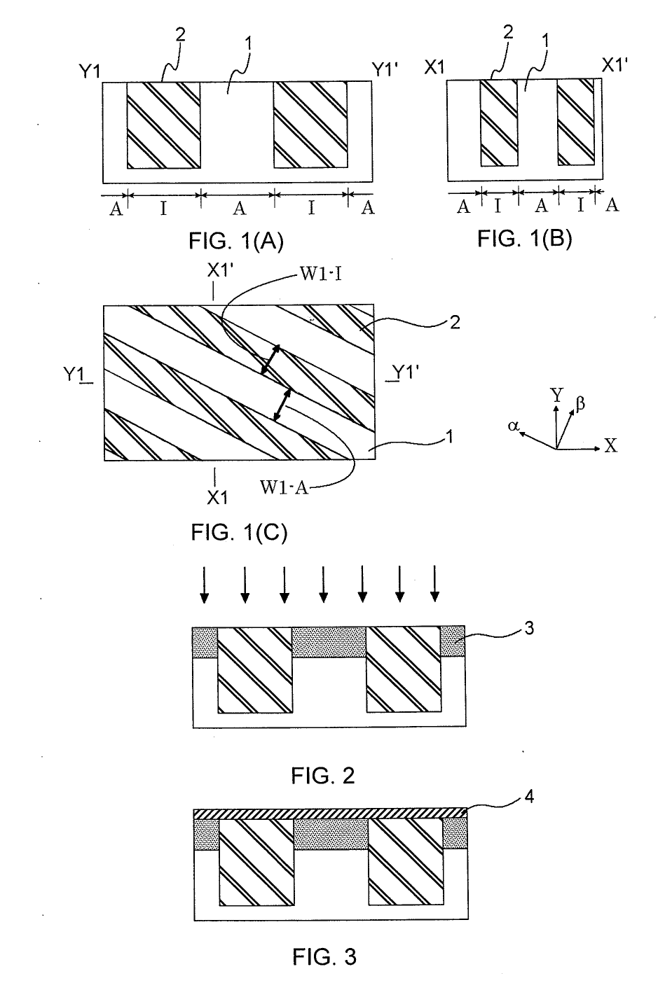

As viewed from the plane, the width W1-I of element-isolating area is 50 nm, the width W1-A of element-forming area is 50 nm, and the depth of element isolation film 2 is 300 nm.

<Process of FIG. 2>

Diffusion layer 3 is formed by introducing an impurity in surface areas of element-forming areas A, which serves as a source or drain of a transistor. Phosphorus is used as the impurity, and is introduced at 30 KeV of energy and 2×10¹³ atoms/cm² of dose by an ion implantation method. The energy and dose are adjusted such that the depth of diffusion layer 3 completed is approximately same as the top position of an embedded gate electrode.

<Process of FIG. 3>

Mask insulation film 4 is formed on the substrate. As a material for this, a silicon oxide film is used, and the thickness of film is 50 nm.

<Process of FIG. 4>

To form a gate trench on the semiconductor substrate, a first resist mask 5 having a first resist opening 5A is formed. The first resist openings 5A have the pattern that the width S5 of opening in X-direction is 40 nm, and these openings are opened with extension in Y-direction, and disposed at the pitch of 80 nm in X-direction. The first resist mask 5 is formed between adjacent first resist openings, which have the width L5 of 40 nm and extended in Y-direction. In this Example, minimum feature size F is 40 nm, and the first resist mask 5 is formed as a line and space pattern using F value.

Mask insulation film 4 is etched using the first resist mask 5. Semiconductor substrate 1 (diffusion layer 3) is exposed in element-forming areas A, and element isolation film 2 is exposed in element-isolating areas I.

Subsequently, the exposed semiconductor substrate 1 and element isolation film 2 are etched to form trenches. These trenches are referred to as gate trench 6. Gate trenches 6 are formed continuously from semiconductor substrate 1 to element isolation film 2. Gate trenches 6A formed in element-forming areas A and gate trenches 6I formed in element-isolating areas I have approximately same depth, i.e., they are formed such that the depth from the main surface of the semiconductor substrate is 200 nm.

Element-forming areas A formed with extension in α-direction are isolated in X-direction by gate trenches 6A to divide pillar-like semiconductors of which planes have the shape of parallelogram (they are referred to as semiconductor pillar 1P). Likewise, element-isolating areas I formed with extension in α-direction are divided in X-direction by gate trenches 6I to isolate pillar-like element isolation films of which planes have the shape of parallelogram (they are referred to as insulator pillar 2P). Semiconductor pillars 1P and insulator pillars 2P are alternately formed in line in Y-direction. Diffusion layer 3 formed on the top surface of semiconductor pillar 1P is divided into a diffusion layer for connection to a bit line that is formed a later process and a diffusion layer for connection to a capacitor; each diffusion layer is referred to as source diffusion layer 3S and drain diffusion layer 3D. In this Example, for convenient, the diffusion layer for connection to a bit line is referred to as source diffusion layer 3S, and the diffusion layer for connection to a capacitor is referred to as drain diffusion layer 3D.

FIG. 4(D) is a cross-section view cut along the line Z2-Z2′ at the height where the diffusion layer of FIG. 4(A) is exist, in which the cross-section is parallel to semiconductor substrate 1. In the figure, the cell unit of CU represents a repetitive unit of a memory cell array of DRAM. For one cell unit CU, source diffusion layer 3S is formed at the center and drain diffusion layers 3D are formed at both side to form two memory cells sharing source diffusion layer 3S. The two memory cells are disposed opposite to each other centered at source diffusion layer 3S. In this figure, the memory cell at the left side of cell unit CU1 is referred as to memory cell CU1-L, and the right side is referred as to memory cell CU1-R. In cell unit CU1, source diffusion layer 3S1 shared by memory cells CU1-L and CU1-R, and drain diffusions layers, i.e. drain diffusion layer 3D1-L formed in memory cell CU1-L and drain diffusion layer 3D1-R formed in memory cell CU1-R are formed. In this figure, cell unit CU2 is formed in adjacent to α-direction-right-lower side. Likewise, cell unit CU2 comprises memory cells CU1-L, CU1-R, source diffusion layer 3S2 formed at the center, and drain diffusion layers 3D2-L and 3D2-R formed at each of the left and right sides.

In the cell unit, a word line is formed in two gate trenches 6 which transverse in Y-direction. This gate trench is referred to as Tr-part gate trench 6T. Gate trench 6 is formed between adjacent cell units to separate cell units. This gate trench is referred to as separate-part gate trench 6S. In this figure, the left side of two Tr-part gate trenches 6T which transverse cell unit CU1 is referred to as Tr-part gate trench 6T1-L, and the right side is referred to as Tr-part gate trench 6T1-R; and the left side of two Tr-part gate trenches 6T which transverse cell unit CU2 is referred to as Tr-part gate trench 6T2-L, and the right side is referred to as Tr-part gate trench 6T2-R. Separate-part gate trench 6SC isolate electrically drain diffusion layers 3D1-R and 3D2-L.

In case of each of drain diffusion layers, in FIG. 4(d), the left and right sides are compartmented by Tr-part gate trench 6T and separate-part gate trench 6S, and the upper and lower sides are formed within the regions compartmented by bit lines 12 (broken lines). For example, in case of drain diffusion layer 3D1-R, the left side is Tr-part gate trench 6T1-R, the right side is separate-part gate trench 6SC, and also the upper and lower sides are compartmented by bit lines.

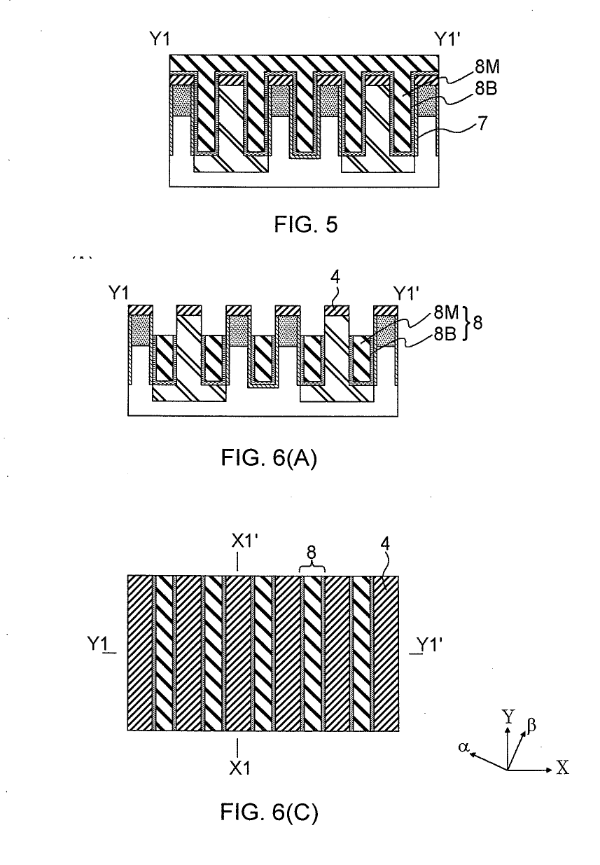

The length in X-direction of a memory cell is referred to as LCX, and the length in Y-direction is referred to as LCY. LCX is defined as a distance from a X-direction-position of a line which transverse in Y-direction from the center of the source diffusion layer to a X-direction-position of a line which transverse in Y-direction from the center of the separate gate trench. Also, the length in X-direction of a cell unit is 2×LCX, and the length of Y-direction is LCY.

<Process of FIG. 5>

The first resist mask 5 is removed.

Gate insulation film 7 is formed on the exposed surface of the semiconductor substrate within gate trench 6. Gate insulation film 7 is a silicon oxide film, and is formed with the thickness of 5 nm by a thermal oxidation method. A material for gate insulation film 7 is not limited to this, but silicon oxide/nitride films or high dielectric films may be used. Also, a method for forming the film is not limited to the method set forth above, but methods such as CVD and ALD may be used.

As a material for a gate electrode, a titanium nitride film as a barrier film and a tungsten film as a metal film are sequentially formed. The thickness of each film is 5 nm and 60 nm. Herein, the titanium nitride film is referred to as gate titanium nitride film 8B, and the tungsten film is referred to as gate tungsten film 8M. Materials for a gate electrode are not limited to these, but doped silicon films and other high melting metal films, or films laminated thereof may be used.

<Process of FIG. 6>

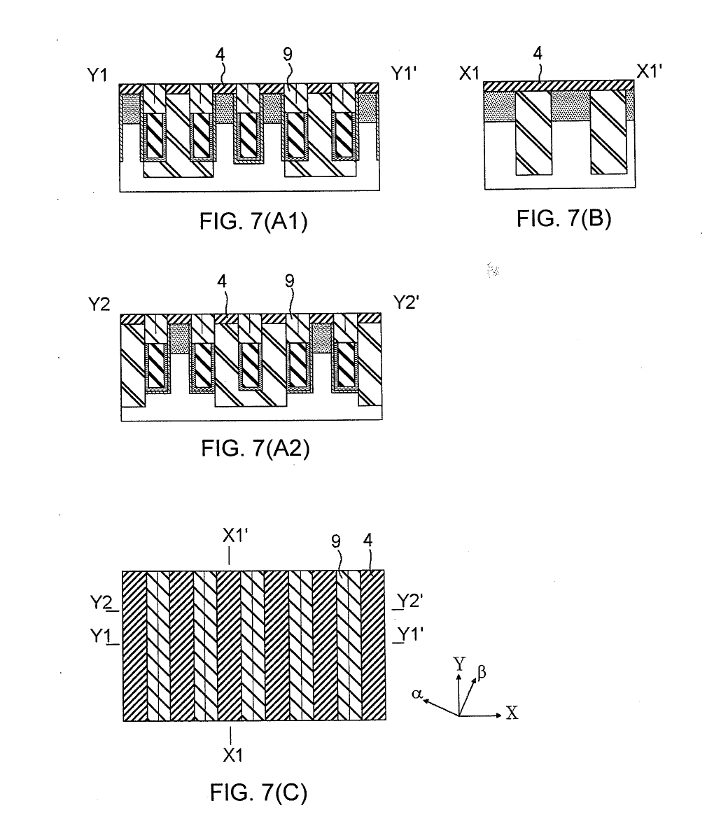

Embedded gate electrodes 8 are formed from gate tungsten films 8M and gate titanium nitride films 8B by a sequential etch-back process. The etch-back process is done such that the top surfaces of gate tungsten film 8M and gate titanium nitride film 8B are positioned at about 100 nm inwardly from the main surface of the semiconductor substrate to form trenches. The height of embedded gate electrode 8 from the lower side of gate trench 6 is 100 nm.

<Process of FIG. 7>

A silicon nitride film having the thickness of 50 nm is formed to fill trenches formed on embedded gate electrodes 8 in gate trench 6. This silicon nitride film is referred to as embedded nitride film 9.

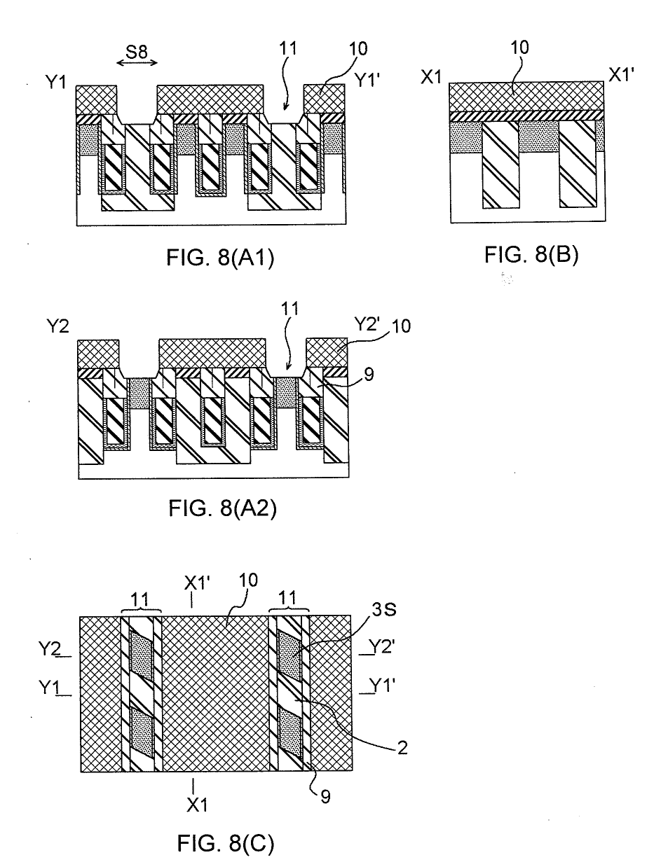

Next, by using an etch-back process, embedded nitride film 9 is embedded on embedded gate electrodes 8 in the gate trench and embedded nitride film 9 on mask insulation film 4 is removed. As viewed from the plane, embedded nitride films 9 having the width of 40 nm and mask insulation films 4 having the width of 40 nm are formed alternately in X-direction.

<Process of FIG. 8>

To form opening on source diffusion layers 3S, a second resist mask 10 having resist opening pattern 10A is formed. Resist opening pattern 10A is formed such that the width of opening in X-direction is 60 nm, openings have an thin pattern opened with extension in X-direction, and one opening is exist on source diffusion layers disposed in Y-direction. The width of opening in X-direction of 60 nm is ensured by adding 10 nm as overlaying margins at both sides of 40 nm-width-source diffusion layer. As a result, the top surfaces of mask insulation film 4 and the embedded nitride film formed in adjacent to the mask insulation film are exposed in the resist opening.

Opening pattern 10A of the second resist mask 10 has an advantage of enabling an effective miniaturization because the resolution margin upon exposure can be improved by virtue of the opening pattern that opens a plurality of source diffusion layers by one opening, when compared to an isolated hole pattern. Mask insulation film 4 is etched using the second resist mask 10 to form opening such that the top surfaces of source diffusion layer 3S and element isolation film 2 underlying mask insulation film 4 are exposed. This opening is referred to as bit line contact opening 11.

The etching process is done under the condition that the etching rate of silicon nitride film is approximately same as the etching rate of silicon oxide film. By this etching process, embedded nitride films 9 opened by the second resist mask 10 are removed while etching mask insulation film 4, and the top surfaces of embedded nitride film 9 etched and source diffusion layer 3S have approximately same height.

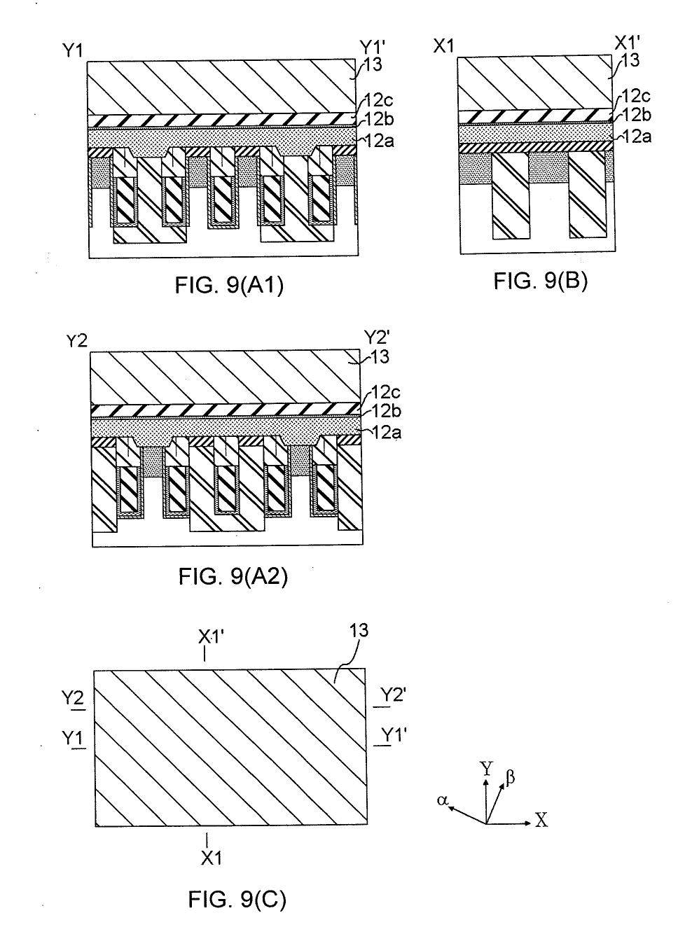

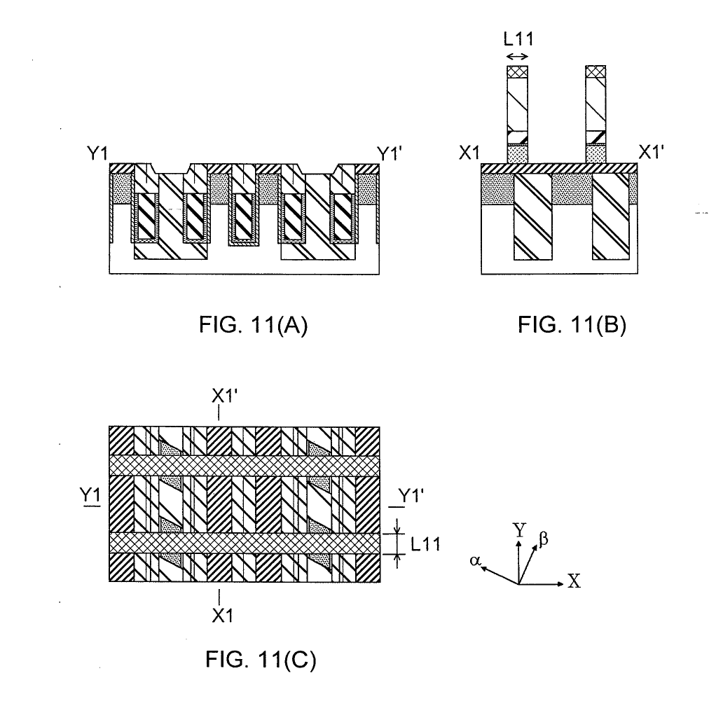

Preferably, the shape of cross-section etched may be a taper-like shape, as shown in FIGS. 8(A1) and 8(A2). Thereby, when patterning additional bit lines in the process of FIG. 11 to prevent bit lines formed in the subsequent process of FIG. 9 from being dis-connected at a bump portion, etching residues generated at the bump portion may be inhibited.

<Process of FIG. 9>

The second resist mask 10 is removed.

As a material for bit line 12, a polysilicon film, a tungsten nitride film and a tungsten film are formed sequentially, and the thickness of each film is 40 nm, 10 nm and 40 nm (each is referred to as bit line polysilicon film 12a, bit line tungsten nitride film 12b and bit line tungsten film 12c). A hard mask having the thickness of 150 nm made of a silicon nitride film is formed thereon (it is referred to as bit line hard mask 13).

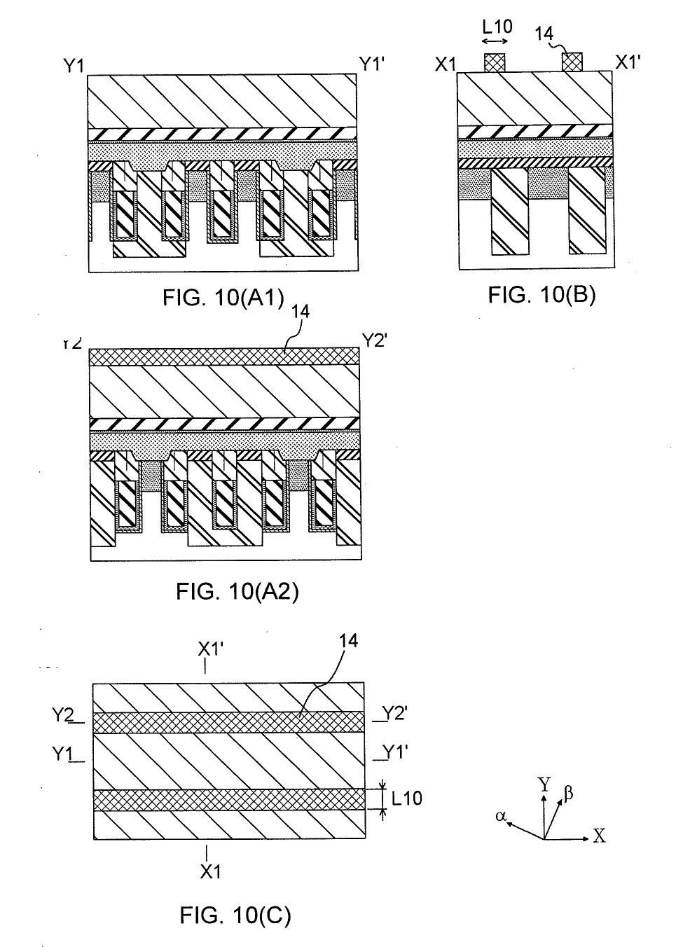

Thereby, source diffusion layers 3S exposed through the bit line contact opening which is opened in the process of FIG. 8 is electrically connected to bit line polysilicon film 12a. Herein, the film-thickness of hare mask 13 is properly adjusted such that the central positions of the upper and lower surfaces in a drain contact plug which is formed in a subsequent process is dislocated by a desired amount.

<Process of FIG. 10>

To pattern a bit line, a third resist mask 14 is formed. The pattern of the third resist mask 14 is formed such that the width L10 in Y-direction is 55 nm, and it has a thin pattern with extension in X-direction. As viewed from the plane, the third resist mask 14 is disposed across source diffusion layers 3S.

<Process of FIG. 11>

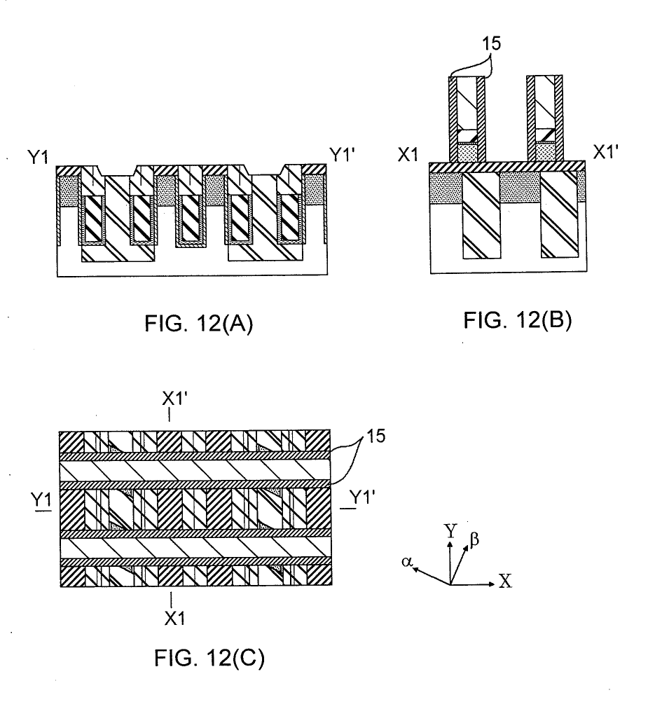

Bit line hard mask 13, bit line tungsten film 12c, bit line tungsten nitride film 12b, and bit line polysilicon film 12a are etched sequentially to form bit lines 12. In this etching process, a 10 nm-thinning treatment is done at one side of the third resist mask 14. As a result, the width L11 of bit line 12 become 35 nm, which is 20 nm thinner than that of the third resist mask 14.

<Process of FIG. 12>

The third resist mask 14 is removed.

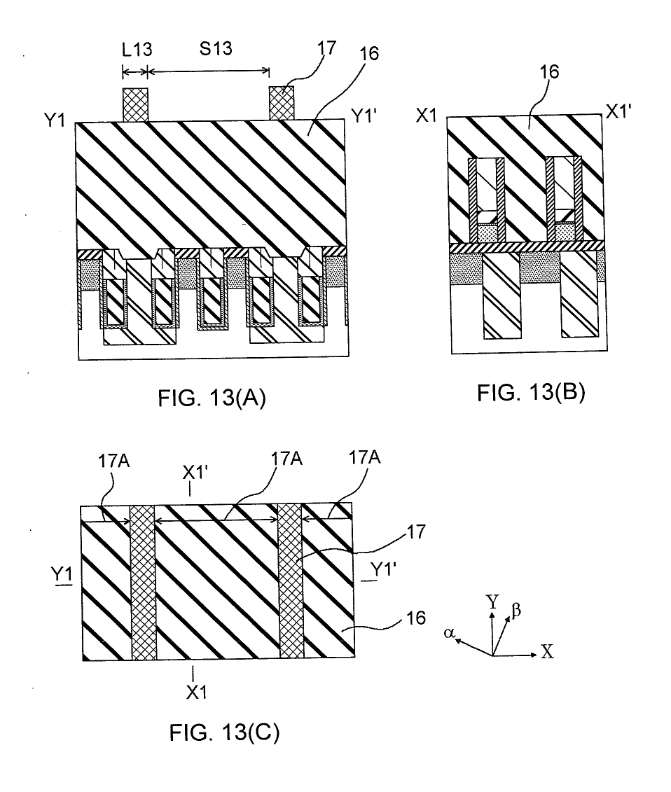

A silicon nitride film having the thickness of 10 nm is formed to cover over the substrate from the surfaces of bit lines 12. This silicon nitride film is referred to as a first side-wall film. A first side-wall 15 having the width of 10 nm is formed on the side walls of bit lines 12 from the first side-wall film by an etch-back process.

<Process of FIG. 13>

A silicon oxide film is grown by 300 nm to fill between bit lines. This silicon oxide film is referred to as a first interlayer film (a first insulation film) 16.

The first interlayer film 16 is polished by CMP method to smooth its surface. It is treated such that the first interlayer film 16 having the thickness of 100 nm remains on bit line hard mask 13.

Drain contact holes 18 are formed on the first interlayer film 16 to form drain contacts which are connected to the top surfaces of drain diffusion layers 3D through the first interlayer film 16.

As viewed from the plane, drain diffusion layers 3D are formed such that the left and right sides are compartmented by the Tr-part gate trench and the separate-part gate trench, and the upper and lower sides are formed within the regions compartmented by bit lines, as described in the process of FIG. 4. Also, the drain diffusion layers are formed as pair-wise layers which are adjacent in X-direction interposed by the separate-part trench gate. The adjacent drain diffusion layers are formed in a point-symmetry manner centered at a desired position on the center-line in X-direction of the separate-part trench gate. Such two drain diffusion layers formed in adjacent to each other (for example, 3D1-R and 3D2-L) are referred to as an adjacent drain diffusion layer pair. The adjacent drain diffusion layer pair is disposed repeatedly in Y-direction at the pitch of LCY. At the centers of the adjacent drain diffusion layer pairs, the separate-part gate trenches having the width F transverse with straight extension in Y-direction, and the adjacent drain diffusion layer pairs are separated by the separate-part gate trenches. As the length in X-direction of the separate-part gate trench is F, the separate-width between the adjacent drain diffusion layer pairs also is F.

A drain contact hole is formed to open the top surfaces of two drain diffusion layers formed in adjacent to each other by one opening. The drain contact hole is formed using such a way that it is opened with self-alignment manner to bit lines in Y-direction, and without compartment by the resist mask in Y-direction. X-direction of the drain contact hole is opened by etching the portions opened by the resist mask. In this resist mask, an opening is formed such that the edge portion of the resist opening is positioned at a position at equivalent distance toward X-directions of the left and right sides from the center position of the adjacent drain diffusion layer pair.

In this Example, a resist mask having the width F is formed to cover over the source diffusion layers at 3 F distance in X-directions of the left and right sides from the center position of the adjacent drain diffusion layer pair. Thereby, the edge portion of the resist mask is positioned at 2.5 F distance toward the left and right sides from the center position of the adjacent drain diffusion layer pair. This resist mask is formed with straight extension in Y-direction. This resist mask is referred to as a forth resist mask 17, and the portions where the resist is opened are referred to as a forth resist mask openings 17A.

The pair of adjacent drain diffusion layers is disposed repeatedly in X-direction at the pitch of 6 F. The source diffusion layers are disposed such that it is positioned at the center between the adjacent pairs of drain diffusion layers. The Source diffusion layers are disposed repeatedly in X-direction at the pitch of 6 F. Thereby, the forth resist mask 17 is disposed repeatedly in X-direction at the line-width L13 of F, the opening-width S13 of 5 F, and the pitch-length of 6 F.

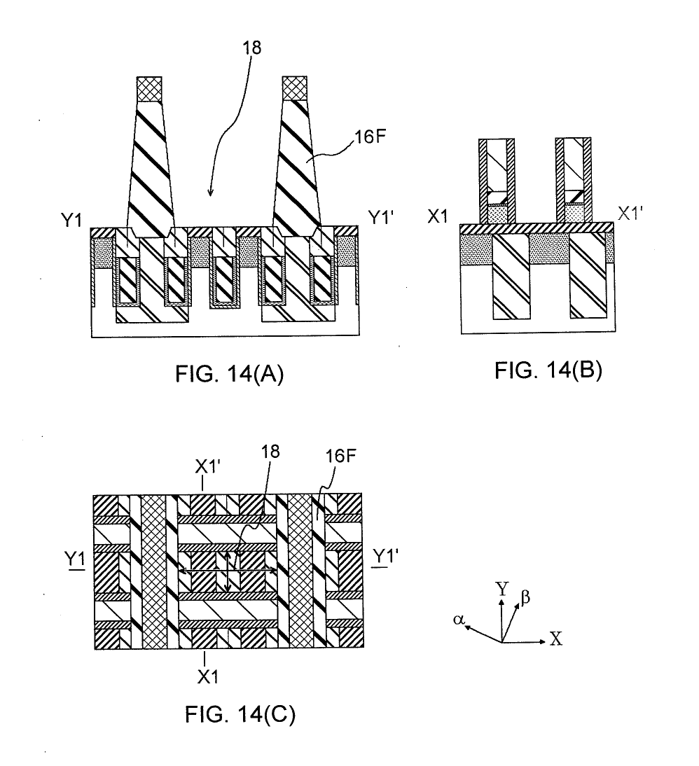

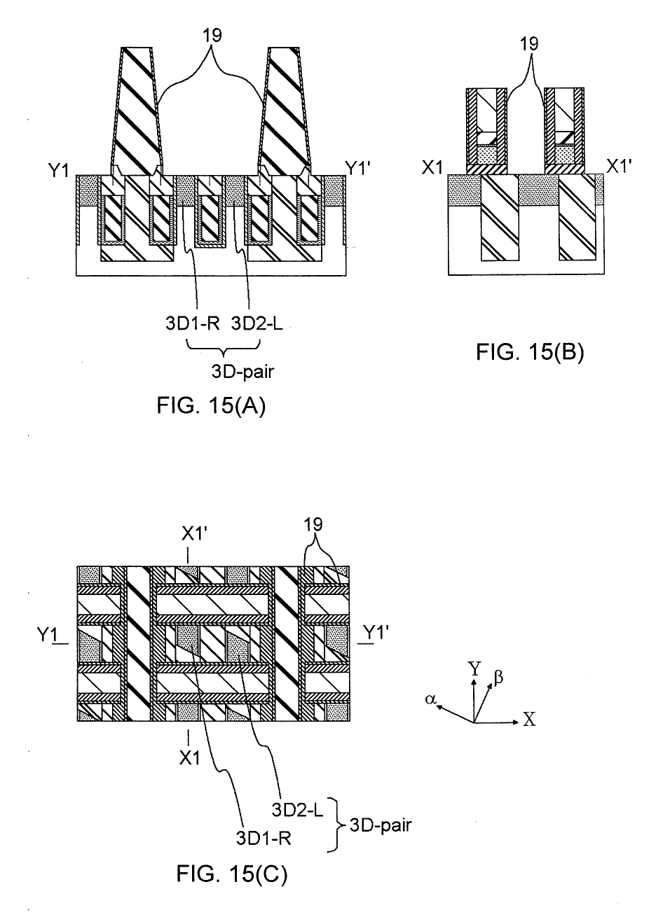

Also, the line-width L13 and the opening-width S13 of the forth resist mask are adjusted such that the source diffusion layers are not exposed while exposing broadly drain diffusion layers 3D in the bottom side of the drain contact hole in processes of FIGS. 14 and 15.

<Process of FIG. 14>

A trench with extension in Y-direction (a first trench) is formed in the first interlayer film 16 by an etching process using the forth resist mask 17 to form opening with self-alignment to bit lines. This opening is referred to as drain contact hole 18. The etching process is done under the condition that the selectivity for a silicon nitride film can be used. Also, the etching process is done such that bit lines 12 are not exposed by leaving bit line hard mask 13 at the top surface of bit line 12 and the first side-wall 15 at the side-wall of bit line 12. The top surfaces of mask insulation film 4 and embedded nitride film 9 are exposed on the substrate.

Drain contact hole 18 is formed such that source diffusion layer 3S is not exposed at an end in X-direction of drain contact hole 18. If source diffusion layer 3S is exposed, an electrical short circuit is caused between source diffusion layer 3S and a pad polysilicon film which is formed in a subsequent process. In this Example, the cross-section in X-direction of drain contact hole 18 has the shape that the opening-width of its upper side is greater than that of its lower side, and the cross-section of the first interlayer film 16 retained underlying the forth resist mask 17 has a trapezoid-like footing shape. This first interlayer film 16 retained underlying the forth resist mask 17 is referred to as a first interlayer fin 16 F. For the first interlayer fin 16 F, the cross-section in X-direction has a trapezoidal shape, and the cross-section in Y-direction is extended beyond bitline 12. The first interlayer fin 16 F over the bit line is positioned at the height of 100 nm above bit line hard mask 13. In this case, a taper angle may be adjusted by a desired extent up to about 45 degree by optimizing the etching condition for the first interlayer film 16. As a result, drain contact hole 18 is sandwiched between bit lines 12 covered by the first side-wall 15 in Y-direction, and between the first interlayer fins 16 F made of the silicon oxide film in X-direction. Also, mask insulation film 4 on the adjacent drain diffusion layer pair and embedded nitride films 9 on separate-part gate trench 6S and Tr-part gate trench 6T are exposed in its bottom side.

<Process of FIG. 15>

The forth resist mask 17 is removed.

A silicon nitride film having the thickness of 5 nm is formed to fill the inside of drain contact hole 18 and to cover over bit lines 12 and the first interlayer fins 16 F. This silicon nitride film is referred to as a second side-wall film.

A second side-wall 19 is formed on the first side-wall 15 of bit line 12 which is a side wall within the drain contact hole and the side wall of the first interlayer fin 16 F from the second side-wall film by an etch-back process, and mask insulation films 4 are removed to expose the top surfaces of drain diffusion layers 3D in the adjacent drain diffusion layer pair (3D-pair). Also, at this time, a portion of embedded nitride film 9 is removed. The process of exposing the top surface of drain diffusion layer 3D by removing mask insulation film 4 may be performed simultaneously with etching the first interlayer film in the process of FIG. 14.

This second side-wall 19 is formed to prevent the first interlayer fin 16 F being etched off during a washing treatment in a subsequent process for forming a pad polysilicon film. If the reduction of the first interlayer film 16 by a washing treatment does not show, the second side-wall 19 may not be formed.

By this process, drain contact hole 18 is sandwiched between bit lines 12 covered by the silicon nitride film (the second side-wall 19) in Y-direction, and between the first interlayer fins 16 F made of the silicon oxide film in X-direction. Also, the top surfaces of drain diffusion layers 3D in the adjacent drain diffusion layer pair and element isolation film 2 as well as embedded nitride films 9 on the separate-part gate trench and the Tr-part gate trench are exposed in its bottom side.

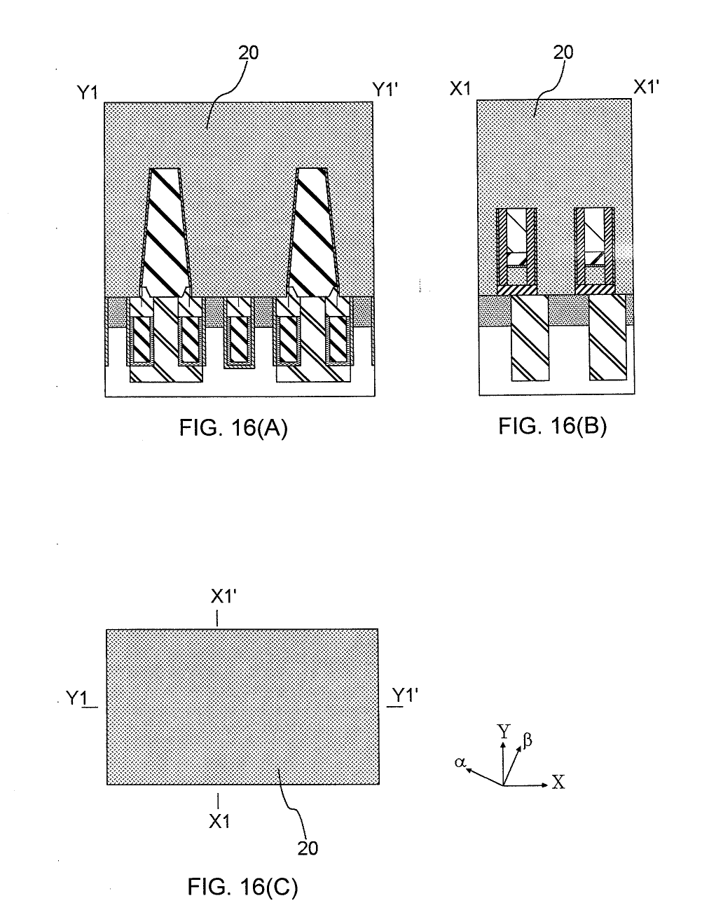

One adjacent drain diffusion layer pair is formed at the bottom side of each drain contact hole. The top surfaces of drain diffusion layers 3D1-R and 3D2-L constituting the adjacent drain diffusion layer pair are exposed at the center of Z1 in FIG. 15.

<Process of FIG. 16>

To remove etching residues on the substrate, a washing treatment is done, and a polysilicon film is grown by 150 nm to fill the inside of the drain contact hole. This polysilicon film is referred to as pad polysilicon film 20.

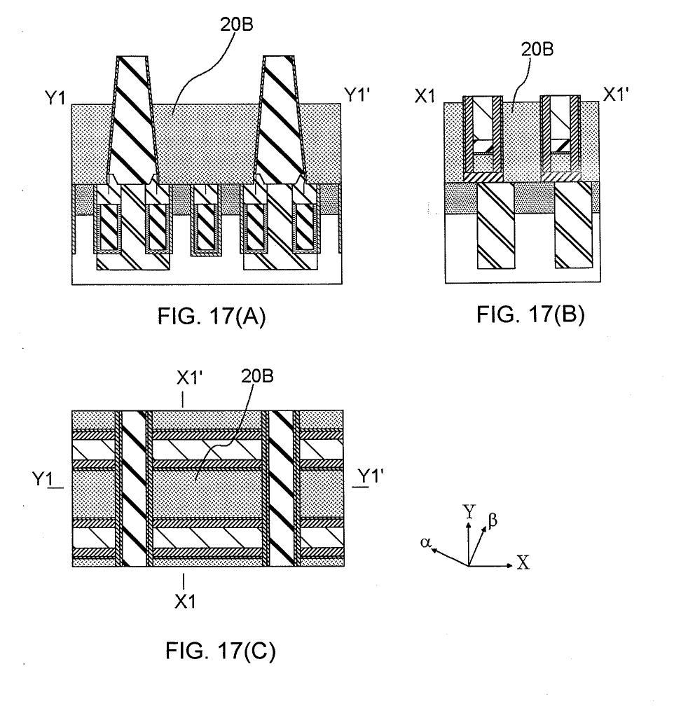

By this process, the top surfaces of drain diffusion layers 3D exposed on the bottom of the drain contact hole are electrically connected to pad polysilicon film 20.

<Process of FIG. 17>

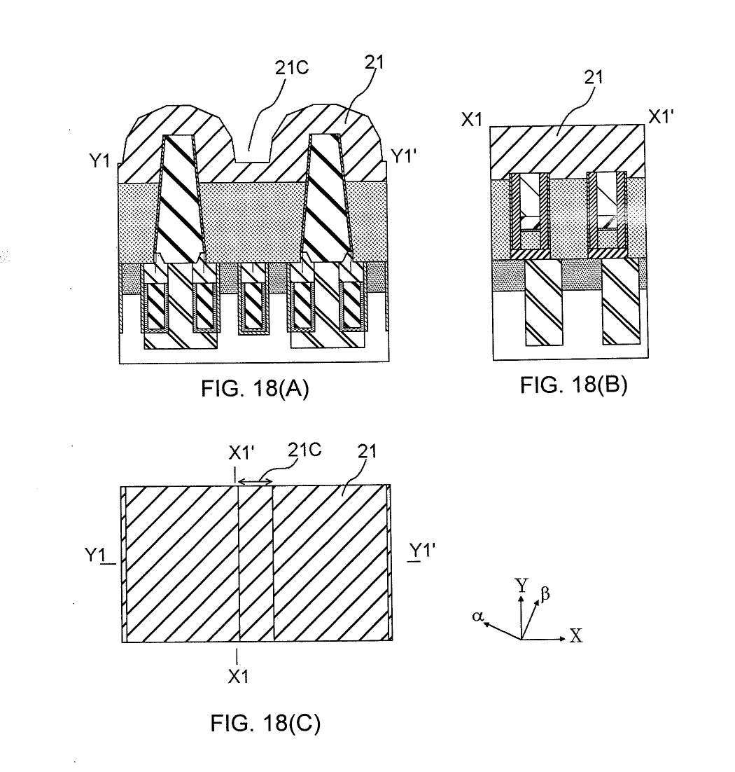

pad polysilicon film 20 is subjected to an etch-back process to expose the top surface of bit line hard mask 13 in the upper side of the bit line, and the pad polysilicon film is embedded into regions compartmented by the first interlayer fins 16 F and bit lines 12. This embedded pad polysilicon film is referred to as pad polysilicon embedded body 20B. Pad polysilicon embedded body 20B is formed within each drain contact hole 18. Also, pad polysilicon embedded body 20B between adjacent drain contact holes 18 is electrically isolated. About 100 nm of the upper side of the first interlayer fin 16 F is projected from the top surface of the substrate, and the projected first interlayer fin 16 F is extended in Y-direction. In this case, the side of the second side-wall 19 in the side of bit line hard mask 13 is not significantly exposed. If the extent of exposure is large, a third side-wall film 12 which is formed in a subsequent process may remain at the side of bit line hard mask 13, and it fails to separate completely pad polysilicon embedded body 20B.

<Process of FIG. 18>

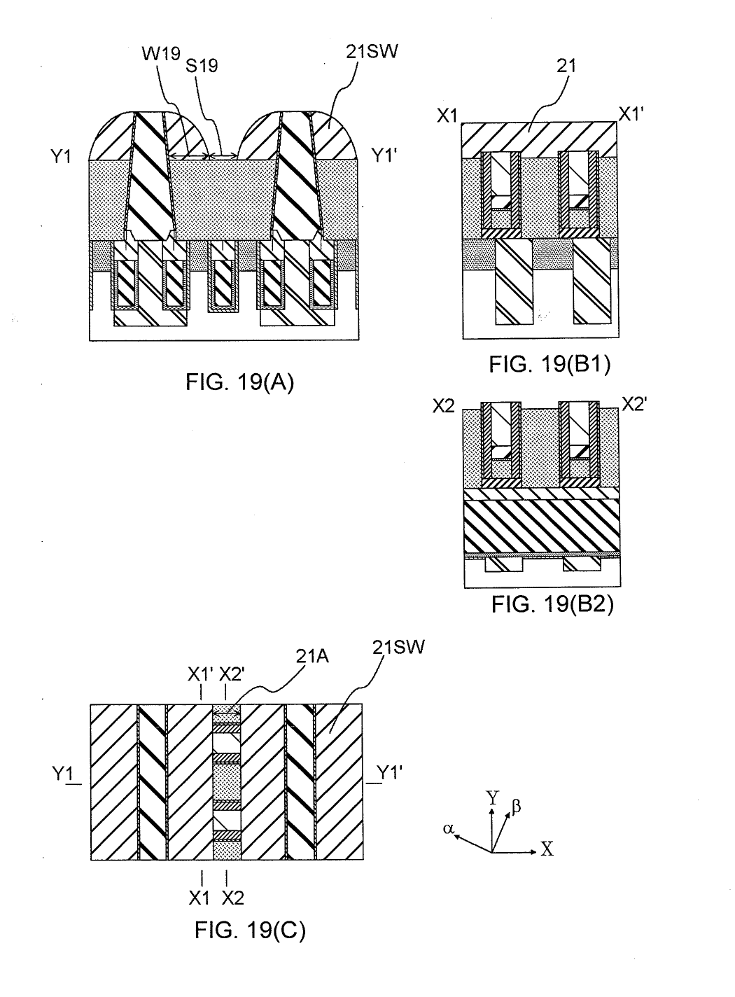

A silicon oxide film having the thickness of 60 nm is formed to cover over bit lines 12 and pad polysilicon embedded bodies 20B from the side and top surfaces of the first interlayer fins 16 F having the height of about 100 nm which are exposed. This silicon oxide film is referred to as a third side-wall film 21. The third side-wall film 21 is formed such that it has a thickness which allows the formation of trench 21C between the first interlayer fins 16 F adjacent to each other in X-direction. Also, the thickness of the third side-wall film 21 may be adjusted depending on the opening-width of a pad polysilicon trench which is formed in the process of FIG. 20.

<Process of FIG. 19>

The third side-wall film is subjected to an etch-back process to form a third side-wall 21SW on the wall surface of the first interlayer fin 16 F. The width in X-direction of the third side-wall 21SW is 60 nm.

A portion sandwiched between the third side-walls 21SW is exposed on the top surface of pad polysilicon embedded body 20B, and the opening-width S19 in X-direction of the exposed portion is 40 nm. This opening is referred to as a third side-wall opening 21A. The third side-wall opening 21A is opened with extension in Y-direction, and the top surface of pad polysilicon embedded body 20B and bit line hard mask 13 on bit lines 12 are exposed through the opening.

<Process of FIG. 20>

Pad polysilicon embedded body 20B is etched using the third side-wall 21SW, the first interlayer fin 16 F and bit line hard mask 13 as a mask under an anisotropic condition to form a trench in the pad polysilicon embedded body. This trench formed in the pad polysilicon embedded body is referred to as pad polysilicon trench 20T. Pad polysilicon embedded body 20B is separated into two parts of the left and right sides in X-direction by pad polysilicon trench 20B. Each of the separated pad polysilicon embedded bodies is referred to as drain contact plug 22. In this Example, the wall surface of pad polysilicon trench 20T also has a taper-like shape, but the wall surface may be formed perpendicularly (taper angle: 0 degree). Generally, the taper angle of the wall surface of the first interlayer fin 16 F is greater than that of the wall surface of pad polysilicon trench 20T such that the area of the top surface of contact plug formed is greater than that of its bottom surface.

The etching process is done under the condition that the selectivity for a silicon oxide film may be used, and bit line 12 surrounded by the second side-wall 19 and the first interlayer fin 16 F may remain.

Embedded nitride film 9 present at the upper side of the separate-part gate trench is exposed in the lower side of pad polysilicon trench 20T. The opening-width S20 of the lower side of pad polysilicon trench 20T is preferably adjusted such that drain diffusion layer 3D is not exposed. By preventing the exposure of drain diffusion layer 3D, drain contact plug 22 may be contacted with drain diffusion layer 3D as close as possible in X-direction, resulting in reducing a contact resistance. Preferably, the opening-width S20 is formed as a small size sufficient such that drain diffusion layer 3D is not exposed, even if a misalignment is caused. In this Example, the opening-width S20 of the lower side is set to 20 nm to produce the alignment margin of 10 nm.

By this process, two drain contact plugs 22 separated into the left and right sides at the center in X-direction are formed within drain contact hole 18, and one drain contact plug 22 is connected to one drain diffusion layer 3D. Thus, the separated pad polysilicon embedded bodies 20B functions as contact plug 22 which is connected to drain diffusion layer 3D.

According to the present invention, by adjusting the thickness of the third side-wall film 31, the width of pad polysilicon trench 20T may be set to smaller size than F value which is the minimum feature size of a photo-lithography, resulting in allowing to set the space-width between adjacent contact plugs 22 to a smaller size that F value.

In a layout of DRAM memory cell, each component is formed using a size close to F value which is the minimum feature size of a photo-lithography. In this Example, the space-width of drain diffusion layers adjacent in X-direction is set to 1 F.

In the related art, to form contacts connected to such drain diffusion layers, one hole-type resist mask opening is formed on one drain diffusion layer, an etching process is performed using it as a mask to open contact holes and form contacts. However, because it is difficult to set the space-width of adjacent contact holes to a size below F value, the space-width of adjacent contact holes is set to 1 F. Therefore, if misalignment is caused, the contact area between the contact and the drain diffusion layer is reduced. Further, using an opening for etching in the related art, because contact holes having taper-like shape may be primarily formed, the bottom side-diameter of the contact hole may be reduced, resulting in further reducing the contact area.

According to the present invention, contact plugs connected to each of two adjacent diffusion layers may be formed such that the space-width between therewith is below F value. As a result, the contact area between the diffusion layer and the contact plug may be ensured sufficiently, and a contact resistance may be reduced.

Also, according to the present invention, since a new photo-lithography process is not added, a production cost is lowered.

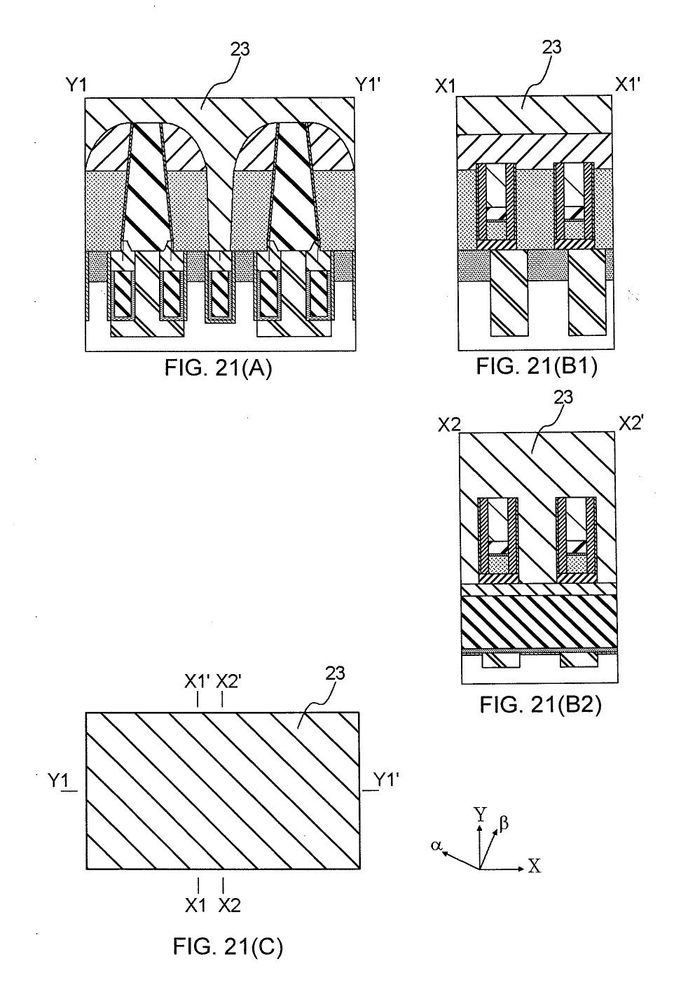

Moreover, according to the present invention, since the opening pattern of contact hole has an opening-width above a width combining two contact holes formed in the related art, the pitch of openings may be slightly widened and the resolution margin upon exposure may be enhanced, resulting in improving a production yield. Thus, the present invention has an advantage that a production cost may be lowered, since an exposure technique having low resolution may be used.

<Process of FIG. 21>

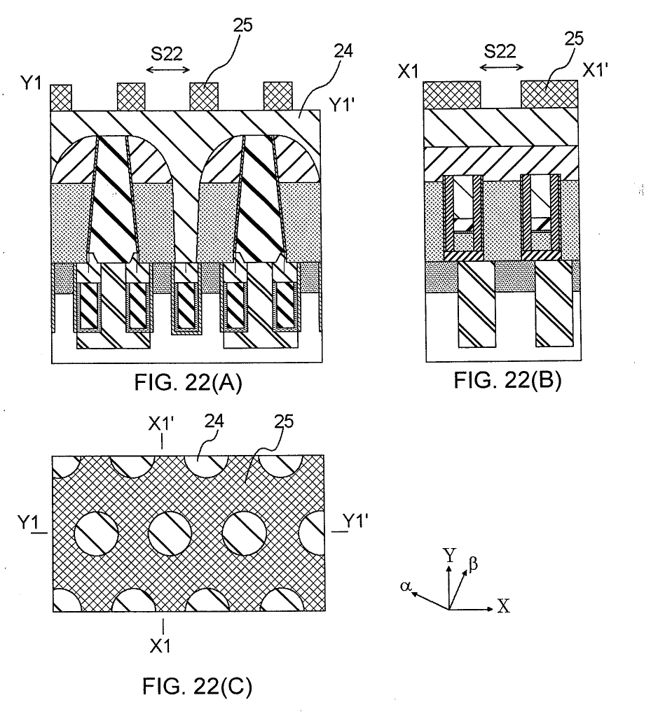

A silicon nitride film having the thickness of 50 nm is formed to fill pad polysilicon trench 20T. This silicon nitride film is referred to as a second interlayer film 23.

<Process of FIG. 22>

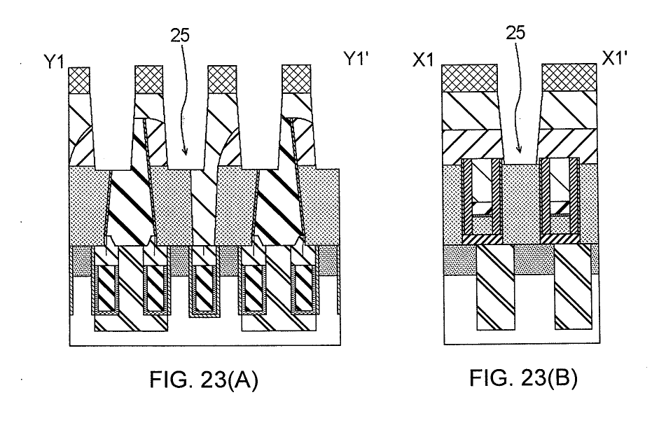

A fifth resist mask 24 is formed to form capacitor contact holes on drain contact plugs 22. Openings for forming the capacitor contact holes are formed on the fifth resist mask 24. The pattern of openings has a hole-like shape, and the diameter S22 of opening is 70 nm. The disposition of openings in the plane corresponds to the disposition of capacitors formed thereon, and they are formed such that the spaces between adjacent capacitors have an equivalent distance.

<Process of FIG. 23>

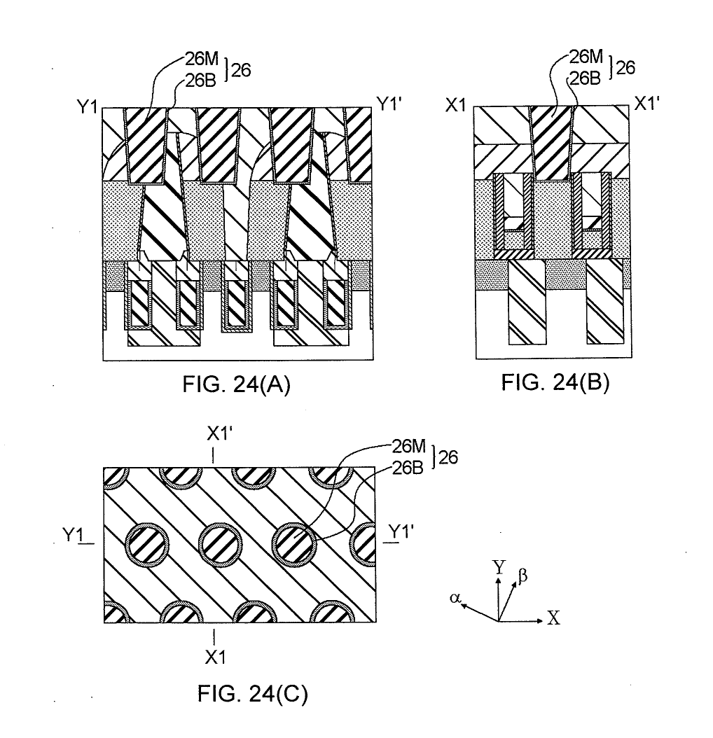

Contact holes are formed through the second interlayer films 23 using the fifth resist mask 24 to open the top surfaces of drain contact plugs 22 and the third side-walls 21SW. This contact hole is referred to as capacitor contact hole 25.

<Process of FIG. 24>

A titanium nitride having the thickness of 5 nm as a material for capacitor contact barrier 26B and a tungsten film having the thickness of 50 nm as a material for capacitor contact plug 26M are sequentially formed. Materials for the capacitor contact plug and capacitor contact barrier are polished by CMP method to form capacitor contact plugs 26 within the capacitor contact holes.

<Process of FIG. 25>

A silicon oxide film having the thickness of 1.5 μm is formed. This silicon oxide film is referred to as capacitor interlayer film 27.

Capacitor electrode holes are formed through capacitor interlayer films 27 to open the top surfaces of capacitor contact plugs 26. An etching process is performed using the second interlayer film 23 made of the nitride film as a stopper film, thereby inhibiting problems such as the arrival of electrode holes on the substrate. In viewed from the plane, capacitor electrode holes are formed at the same positions as capacitor contact plugs 26.

Capacitor lower electrode 28 covering from the side to bottom of capacitor electrode hole is formed.

Capacitor insulation film 29 is formed on capacitor lower electrode 28.

A capacitor upper electrode film is formed on capacitor insulation film 29.

The capacitor upper electrode film is patterned to form capacitor upper electrode 30.

Upper interlayer film 31 is formed on the capacitor upper electrode.

Contacts are formed to connect elements formed on the semiconductor substrate (not shown).

Upper wiring 32 comprising upper wiring barrier film 32B and upper wiring main wiring film 32M is formed, which is connected to contacts.

Next, if necessary, further interlayer films, contacts, wiring and protective films are formed to complete a semiconductor device.

FIG. 25(E) is a partial cross-section view of cell unit CU1 cut along the line A1-A1′ in α-direction of FIG. 25(D). Source diffusion layer 3S1 is formed at the center, bit line 12 is connected on source diffusion layer 3S1, Tr-part gate trench 6T1-L and drain diffusion layer 3D1-L are formed at the left side of source diffusion layer 3S1, and Tr-part gate trench 6T1-R and drain diffusion layer 3D1-R are formed at the left side of source diffusion layer 3S1. Drain contact plug 22, capacitor contact plug 26 and capacitor lower electrode 28 are formed on each drain diffusion layer. A DRAM memory cell comprising embedded gate electrodes 8 formed within Tr-part gate trenches 6T, word lines, capacitors, and bit lines is constructed. FIG. 25(D) is a cross-section view cut along the line Z4-Z4′ of FIG. 25(A). Capacitor contact plug 26 is disposed in each drain contact plug 22. The disposition of capacitor contact plugs in the plane corresponds to the disposition of capacitors formed thereon, and they are disposed such that the spaces between adjacent capacitors have an equivalent distance.

### Example 2

In Example 1, capacitor contact plug 26 is formed between drain contact plug 22 and capacitor lower electrode 28, and capacitor electrode hole having a deep depth is formed by an etching process using the second interlayer film 23 made of the nitride film as a stopper film.

If the etching depth of capacitor electrode hole can be controlled, it is possible to form the capacitor electrode hole without forming capacitor contact plug 26. A method for performing this approach is described in Example 2.

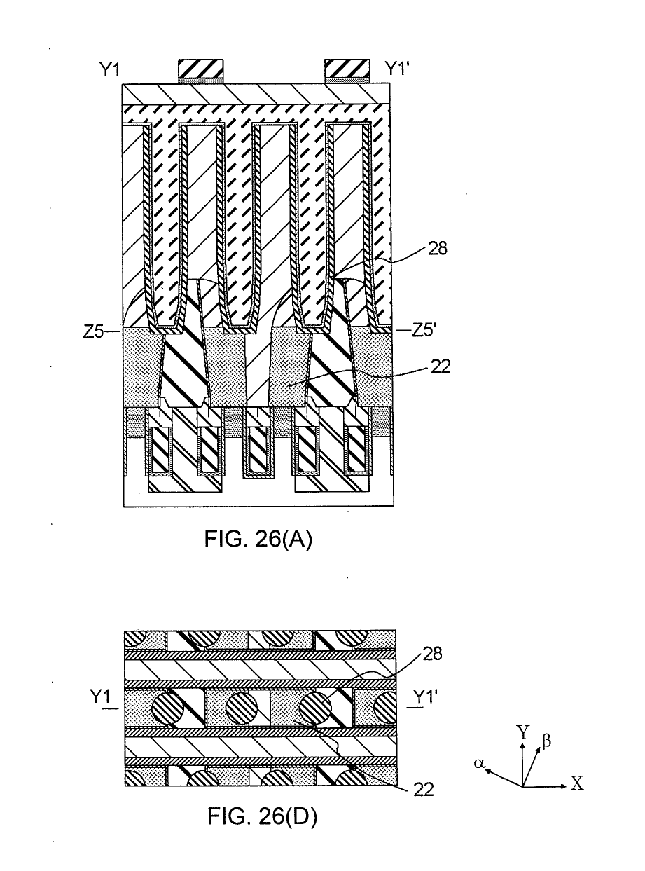

FIG. 26 is a view illustrating Example 2. FIG. 26(D) is a cross-section view cut along the ling Z5-Z5′ of FIG. 26(A), in which the cross-section is parallel to the semi-conductor substrate. FIG. 26(A) is a cross-section view cut along the line Y1-Y1′ according to Y-direction shown FIG. 26(D), in which the cross-section is perpendicular to the semi-conductor substrate.

The processes of FIGS. 1 to 20 described in Example 1 are also used in Example 2.

After the process of FIG. 20 described in Example 1, capacitor interlayer films 27 are formed as in the process of FIG. 25 described in Example 1.

Capacitor electrode holes are formed through capacitor interlayer films 27 to open the top surfaces of drain contact plugs 22. An etching process is done such that the contact holes do not reach the substrate. The disposition of capacitor electrode holes in the plane is the same disposition as in Example 1.

Next, a memory cell is completed by performing the same process as in FIG. 25 of Example 1.

### Example 3

In Example 1, pad polysilicon film 20 is embedded into the drain contact hole, and the etch-back process is performed until the top surface of bit line hard mask 13 is exposed. In this etch-back process, the height of pad polysilicon film 20 is lower than that hard mask 13 to remove completely pad polysilicon film 20 on the bit line, because if pad polysilicon film 20 remains on the bit line, drain contact plugs 22 in Y-direction may not be isolated, resulting in causing a short circuit. To the contrary, if it is etched back by a deep area sufficiently from bit line hard mask 13, the third side-wall film may remain on the wall surface of the bit line, resulting in failing to isolate sufficiently drain contact plugs 22 in X-direction, as described above. Thus, the etch-back of pad polysilicon film 20 within a wafer should be performed uniformly.

Thus, in Example 3, when pad polysilicon film 20 is etched back, a method for improving the etch-back-uniformity of pad polysilicon film 20 is described. By using this method, even if pad polysilicon film 20 remains above hard mask 13, a short circuit in Y-direction between drain contact plugs 22 may be prevented.

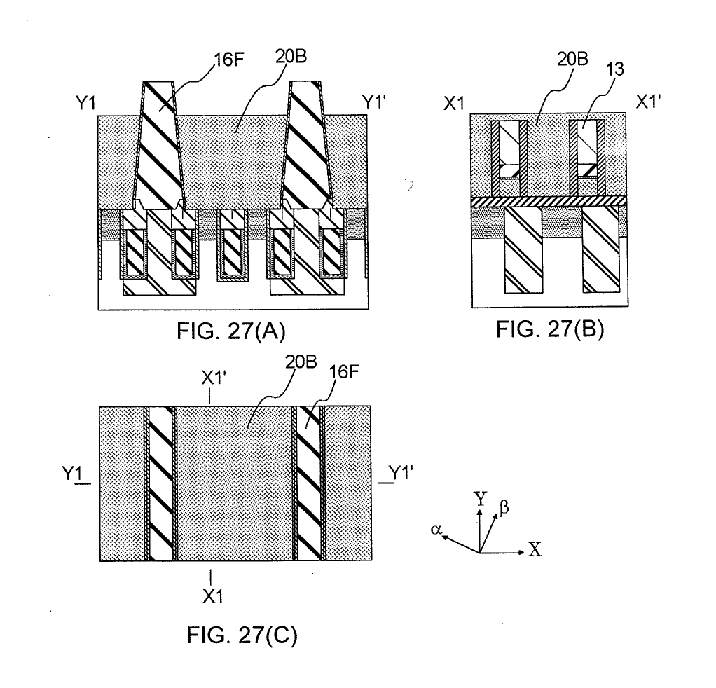

With respect to FIGS. 27 to 32, the method according to Example 3 of the present invention is described.

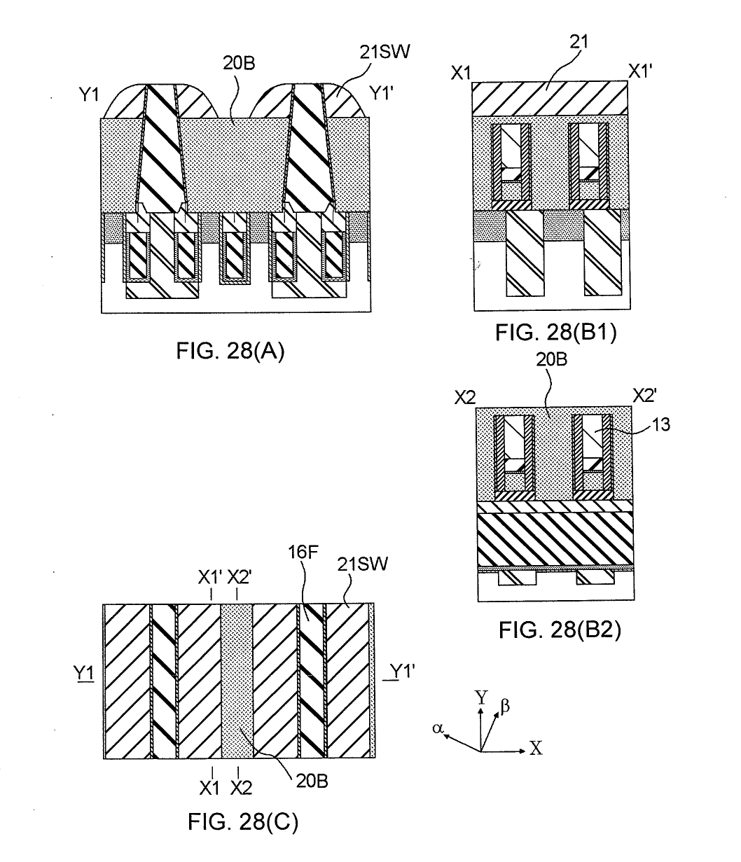

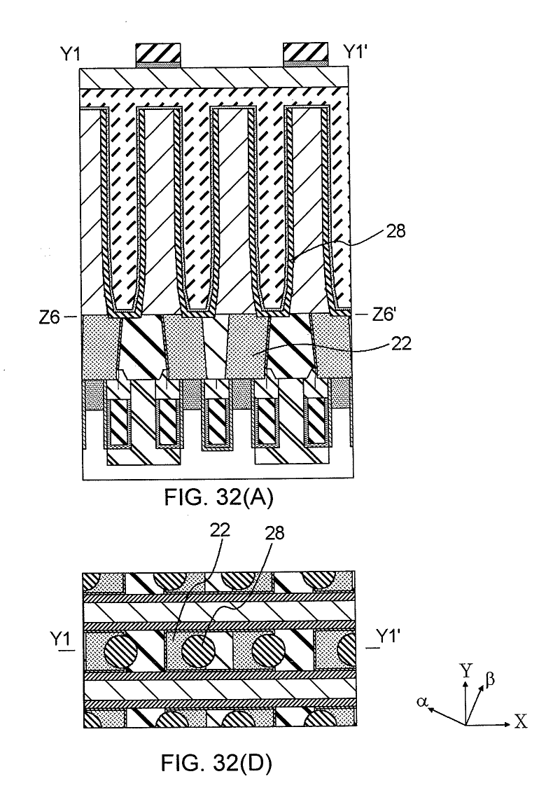

As in Example 1, X-direction, Y-direction, α-direction and β-direction are defined as indicated in FIG. 27(C). Sub figures (C) in each figure are a top view; FIG. 32(D) is a cross-section view cut along the line Z6-Z6′ of FIG. 32(A), in which the cross-section is parallel to the semiconductor substrate; FIG. 27(B) and FIGS. 28(B1) to 31(B1) are a cross-section view cut along the line X1-X1′ according to X-direction shown in the corresponding sub figures (C), in which the cross-section is perpendicular to the semiconductor substrate; FIGS. 28(B2) to 31(B2) are a cross-section view cut along the line X2-X2′ according to X-direction shown in the corresponding sub figures (C), in which the cross-section is perpendicular to the semiconductor substrate; and sub figures (A) in each figure are a cross-section view cut along the line Y1-Y1′ according to Y-direction shown in the corresponding sub figures (C) or (D), in which the cross-section is perpendicular to the semiconductor substrate.

The processes of FIGS. 1 to 16 described in Example 1 are also used in Example 3.

<Process of FIG. 27>

The etch-back of pad polysilicon film 20 as described in the process of FIG. 17 of Example 1 is performed such that this film remains on the top surface of bit line hard mask 13 as shown in FIG. 27. However, the top surface of bit line hard mask 13 may be exposed depending on positions.

<Process of FIG. 28>

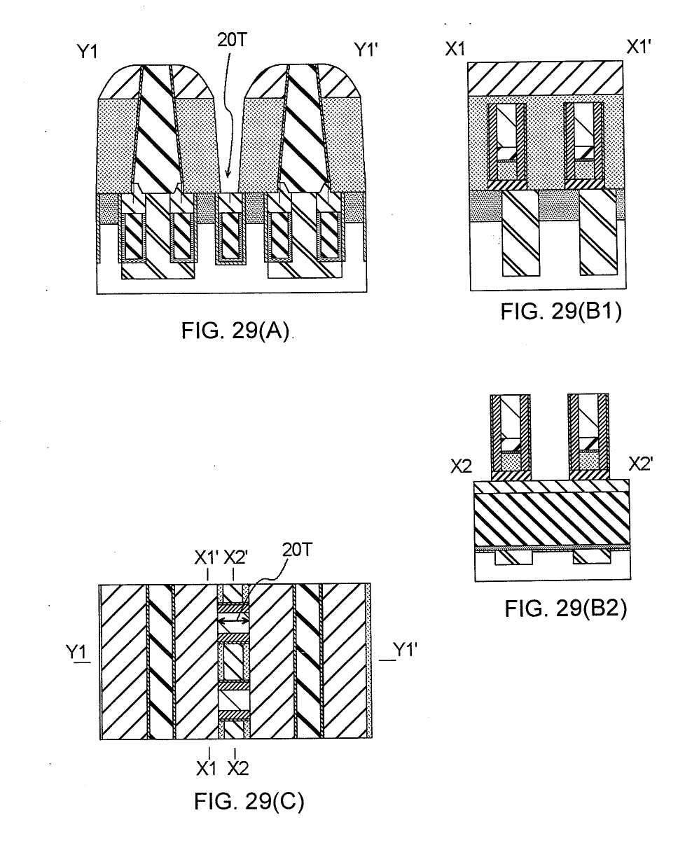

The third side-wall film 21 is formed using the same process as in FIG. 18 of Example 1. The film-thickness is 60 nm. In this case, the film-thickness may be adjusted depending on the opening-width of the bottom side of pad polysilicon trench 20T which is formed in the process of FIG. 29.

The third side-wall film is subjected to an etch-back process as in FIG. 19 of Example 1 to form the third side-wall 21SW.

<Process of FIG. 29>

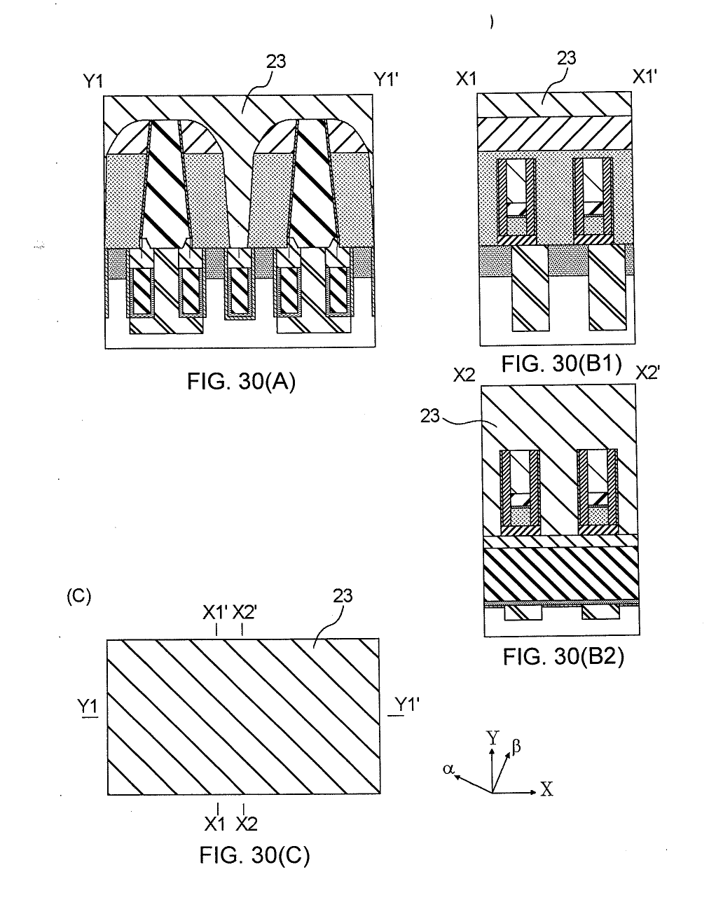

pad polysilicon film 20 is etched using the same process as FIG. 20 of Example 1 to form pad polysilicon trench 20T. In this stage, in case of the process of FIG. 20 described in Example 1, as shown in FIG. 29(A), pad polysilicon films 20 are separated into the left and right sides in X-direction, and one pad polysilicon film 20 is formed in one drain diffusion layer. However, as shown in FIG. 29(B1), pad polysilicon films 20 are electrically connected over the bit lines in Y-direction.

<Process of FIG. 30>

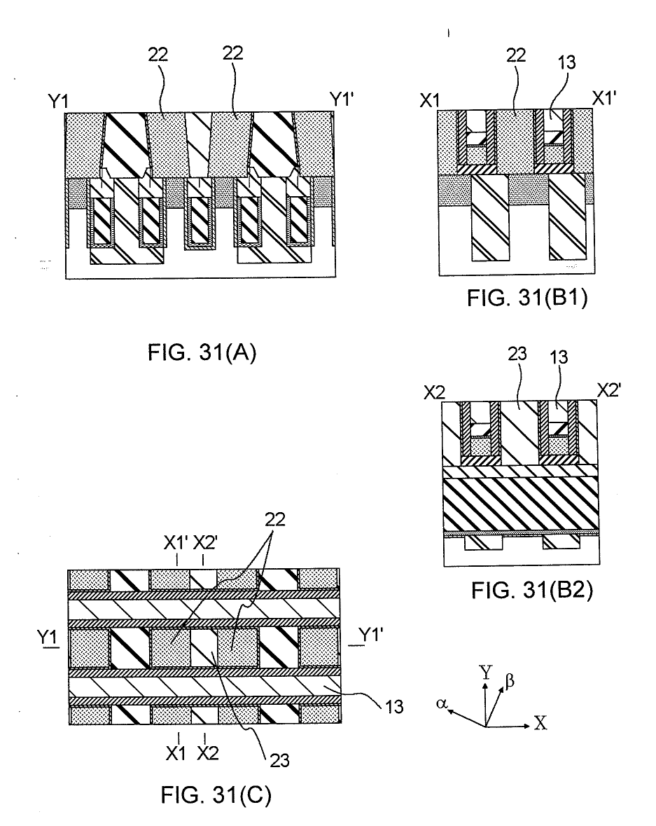

The second interlayer film 23 having the thickness of 50 nm made of a silicon nitride film is formed to fill pad polysilicon trenches 20T.

<Process of FIG. 31>

The second interlayer film 23, the first interlayer fin 16 F, and bit line hard mask 13 are polished by CMP method to remain bit line hard mask 13. In this case, bit line tungsten film 12M constituting bit lines 12 should not be exposed.

By this process, pad polysilicon films 20 connected over the bit lines in Y-direction are isolated in Y-direction by bit lines 12, and one pad polysilicon film is connected to one drain diffusion layer 3D (drain contact plug 22).

<Process of FIG. 32>

Next, after the process of forming the capacitor interlayer film, the subsequent process is performed as in FIG. 26 of Example 2. Alternatively, the capacitor interlayer film may be formed after the process of FIG. 31, the same processes as FIGS. 21 to 24 of Example 1 may be performed to form capacitor contact plug 26.

Thus, in this Example, in case of the etch-back of pad polysilicon film 20, the uniformity within a wafer is not required, and it is possible to connect one drain contact plug 22 to each drain diffusion layer 3D.

Although the contact plugs according to the present invention are used as contact plug (drain contact plug) connected to the substrate in Examples 1 to 3, the present invention is not limited to these contact plugs. For example, drain contacts may be usually formed, and the contact plugs according to the present invention may be used as capacitor contacts which are connected to the drain contacts. In this case, the shape of cell transistor is not limited to an embed-type gate structure, and a gate electrode may be formed on the substrate, such as a recess-type gate structure. In addition, the contact plug according to the present invention may be used as the drain contact plug and the capacitor contact plug. Moreover, although pad polysilicon film is embedded into the drain contact hole as a conductive material, the present invention is not limited to this material, and other conductive materials, for example metal films or metal compound films such as W/TiN/Ti, WSi, TiN/Ti, TiN, and the like may be used.

### Example 4

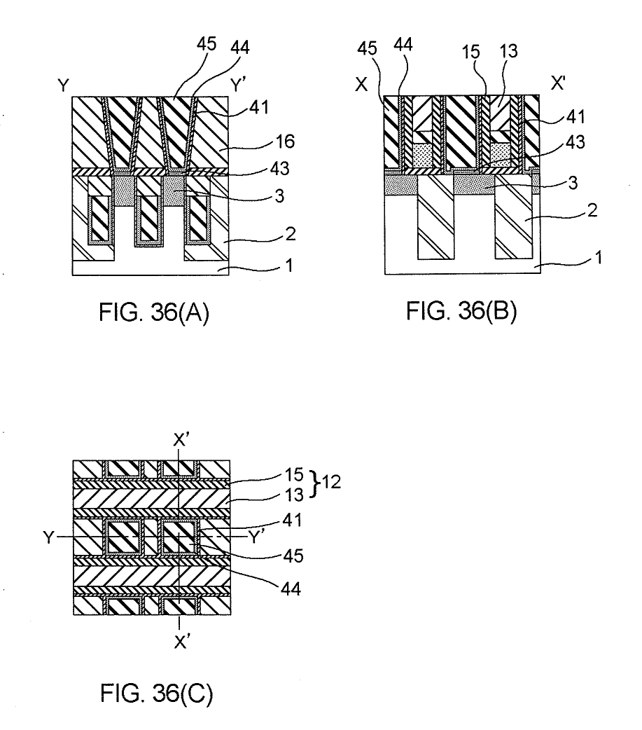

The area of capacitor contact is reduced and a contact resistance is increased with miniaturization. When a metal plug is used as a contact plug, a contact resistance may be reduced, however, in terms of capacitor contact, a refresh property is deteriorated, or an embedding property is deteriorated with respect to a conventional fine contact hole. For example, FIG. 36 shows a contact having a metal structure (W/TiN/Ti/CoSi) in the related art.

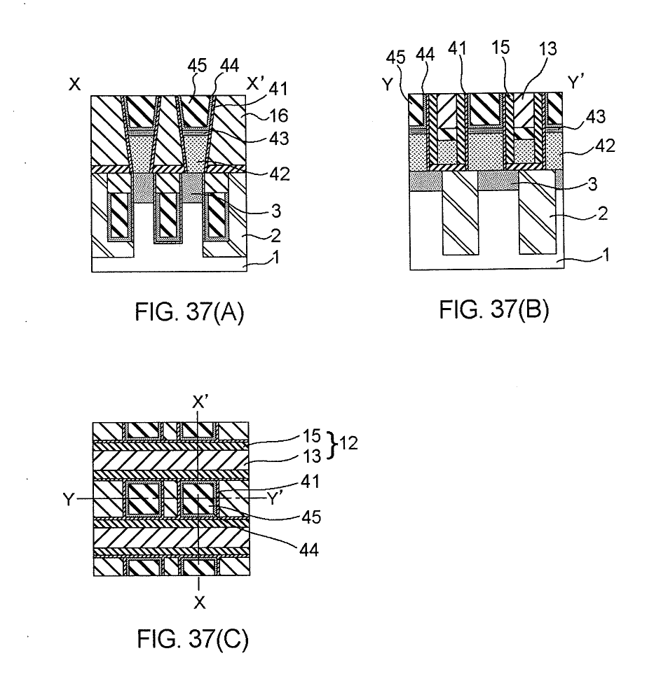

To help understand, FIGS. 36 and 37 show the case that a drain contact is formed with respect to an embedded gate-type transistor, as described in Example. Therefore, these figures are made by the inventors for explanation, and do not show the related art itself.

After performing the processes of FIGS. 1 to 12, a first interlayer film 16 is formed as in the process of FIG. 13 with the exception that it is not formed as a fin shape, and a planarization process is performed up to the top surface of bit line hard mask 13. In related art, individual contact hole is formed, or trenches are formed. using a mask having a line pattern to expose diffusion layers one by one in Y-direction. Herein, trenches are formed using a line pattern oriented in a direction orthogonal to the bit line. Next, side-wall 41 is formed on the wall surface of the formed trenches, wherein side-wall 41 is made of a silicon nitride film. Side-wall 41 functions as a barrier to prevent a cobalt film for forming cobalt silicide being diffused into the first interlayer film 16 during forming the silicide. After forming a metal film, for example cobalt film by a known method, metal silicide film 43 is formed by reacting the metal film with silicon in the substrate by a heat treatment. Next, unreacted cobalt film is removed. If the metal film is formed directly on the silicon substrate, a Schottky-contact is obtained. However, a good Ohmic-contact is obtained by the formation of metal silicide film 43

Next, after forming TiN/Ti barrier film 44 and tungsten (W) film by a known method, an etch-back process is performed until bit line hard mask 13 is exposed. Thereby, a metal plug having the structure as shown in FIG. 36 is obtained.

To solve the deterioration of a refresh property or an embedding property with respect to a conventional fine contact hole, the hybrid structure as shown in FIG. 37 may be used. The hybrid structure as shown in FIG. 37 is formed by embedding polysilicon film 42 on the bottom of contact hole, and forming a metal plug (TiN/Ti barrier film 44 and tungsten (W) film 45) thereon via a metal silicide film 43, for example cobalt silicide. The deterioration of a refresh property is primarily caused by a reduction in the adhesion-depth of diffusion layer during the formation of metal silicide film 43. This deterioration of refresh property may be inhibited by increasing a volume by the formation of polysilicon film 42 on the substrate 42. Further, by forming polysilicon film 42, the contact hole is shallower than a previous state, thereby improving the embedding property of metal film due to a low aspect ratio.

In this Example, a manufacturing example of this hybrid structure using the method according to the present invention is described.

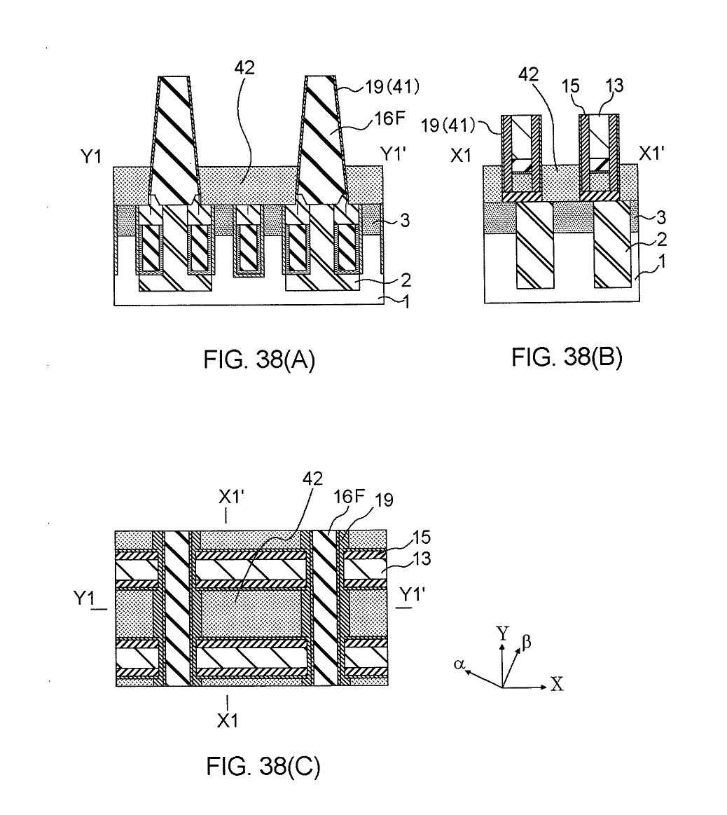

FIG. 38 shows the contact plug of hybrid structure formed by using the method according to the present invention. As shown in FIG. 38, in the hybrid structure according to this Example, by removing TiN/Ti barrier film 44 in one side (surface in contact with insulation film 46) of metal plug on the top of the hybrid structure, the area of W film 45 is increased. Also, the contact area between polysilicon film 42 and diffusion layer 3 in the bottom surface, thereby reducing a contact resistance as compared to the conventional hybrid structure as shown in FIG. 37. Moreover, the area where the metal film for silicide and the metal film for metal plug are embedded is about three times than the structures as shown in FIGS. 36 and 37, thereby further improving an embedding property.

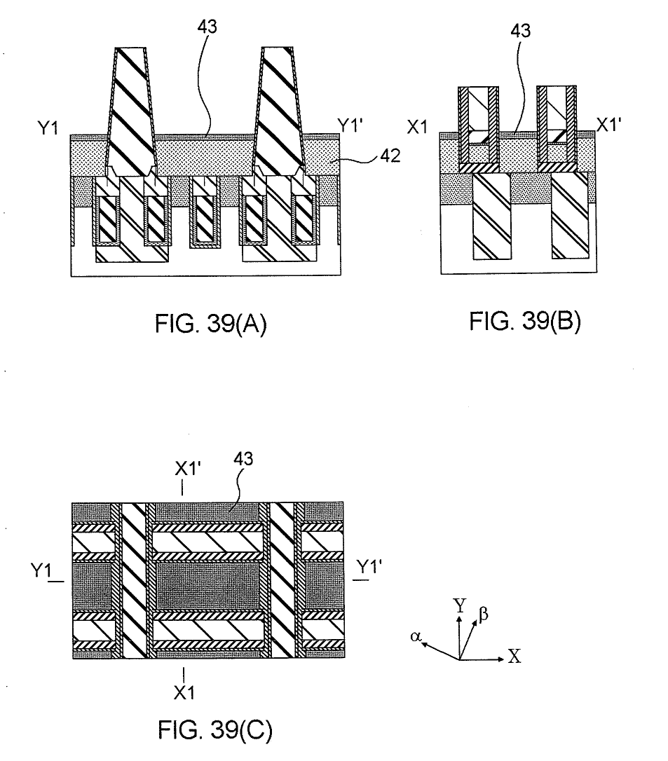

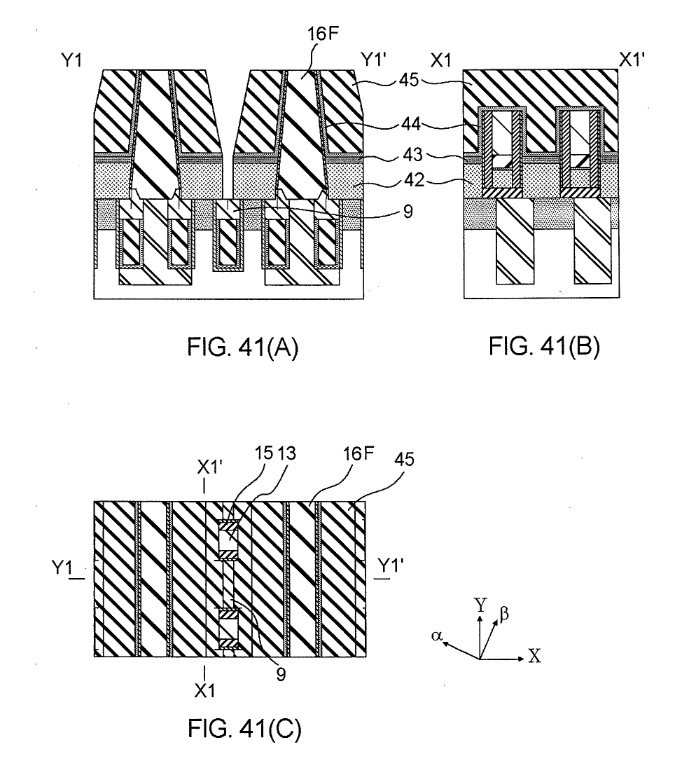

Next, a method for forming the hybrid structure according to this Example is described. FIGS. 39 to 42 are process cross-section views showing a manufacturing example of the hybrid structure according to this Example. In each figure, sub figure (A) is a cross-section along the line Y1-Y1′ of the plane view sub figure (C), and sub figure (B) is a cross-section along the line X1-X1′ of the plane view sub figure (C), First, after forming up to the second side-wall 19 in the process of FIG. 15, pad polysilicon (DOPOS) film 20 is formed by the same method. Provided that, in this example, in consideration of an embedment property between fine bit wiring, a laminated film where a plasma oxidation film is formed on an applied insulation film (Spin On Dielectric: SOD film) was used as the first interlayer film 16. Also, the thickness of the second side-wall 19 is 10 nm. Next, an etch-back process is done while leaving about 50 nm from the diffusion layer (FIG. 39). The remaining polysilicon film is referred to as DOPOS film 42.

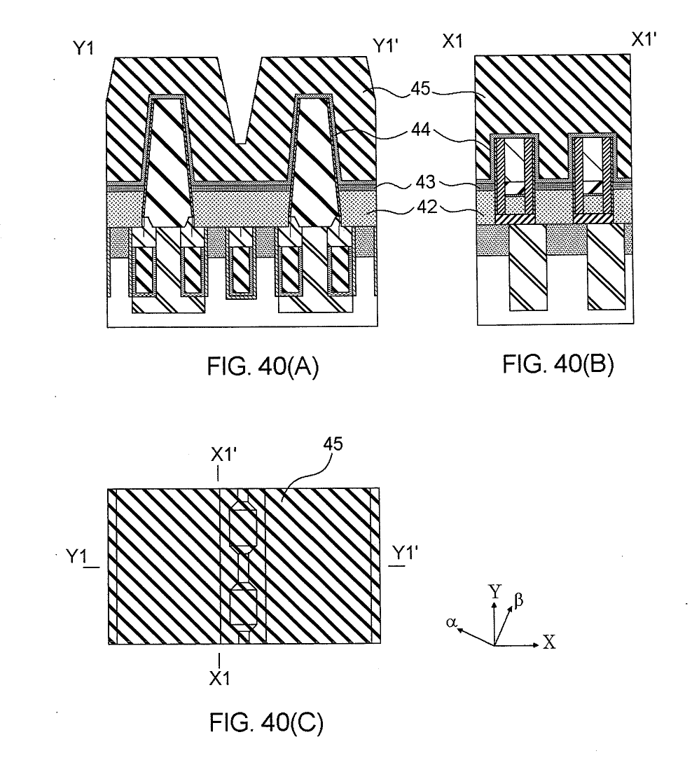

Next, after forming a cobalt film on the entire surface by a sputtering method and subjecting to a heat treatment, then unreacted cobalt film is removed to form cobalt silicide film 43 on DOPOS film 42, as shown in FIG. 40.

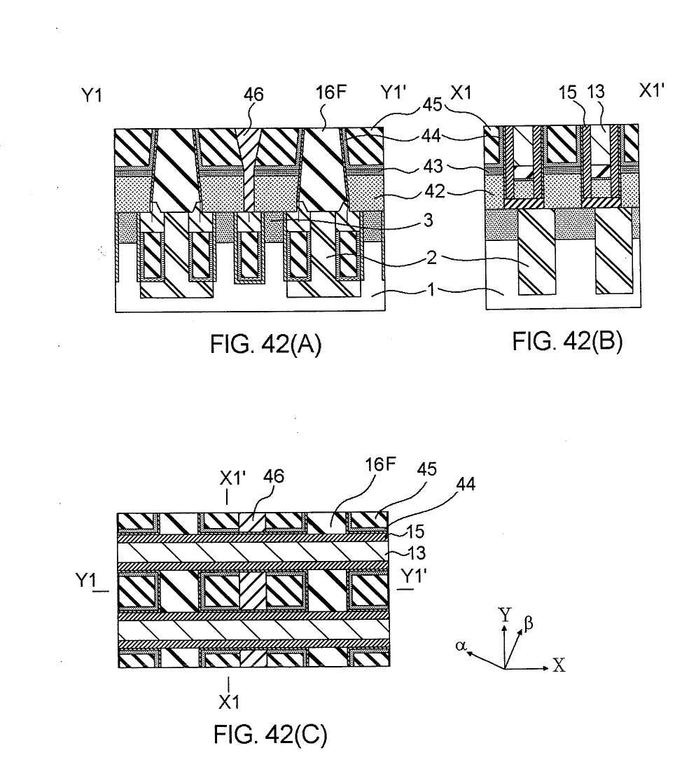

Barrier film 44 comprising the laminated TiN/Ti and tungsten (W) film 45 are formed (FIG. 45). Next, W film 45, barrier film 44, cobalt silicide film 43 and DOPOS film 42 are sequentially etched back using an inductively coupled plasma etcher (FIG. 42). An etch-back condition for each film is as follows:

W film: SF₆/Cl₂/N₂=40/60/30 sccm, Pressure=1.3 Pa (10 mTorr), Source power=800 W, Bias power=50 W

TiN/Ti/CoSi: CF₄/Cl₂/BCl₃=20/40/120 sccm, Pressure=1.3 Pa (10 mTorr), Source power=800 W, Bias power=50 W

DOPOS: HBr/N₂/O₂=250/50/5 sccm, Pressure=2.7 Pa (20 mTorr), Source power=400 W, Bias power=90 W

Under these conditions, after the etch-back of W film 45, each film underlying W film 45 is etched using W film 45 as a mask. That is, the etched back W film 45 replaces the third side-wall 21S in the previous Example.

After the etch-back process, insulation film 46 is embedded within the separated trenches, and a planarization process is performed by CMP method until hard mask 13 on the bit lines is exposed. Thereby, the contact plug having the hybrid structure is obtained as shown in FIG. 38. Further, since the space-width of the bottom surfaces in plug pairs of the hybrid structure obtained by the separation may be controlled by the thickness of W film 45, the width may have a width below the minimum feature size F value. Of course, as in the previous Example, the third side-wall 21S is formed from an insulation film to perform the separation. However, in this case, first, W film 45 is planarized, and further etched back to expose the side-wall of the first interlayer fin 16, resulting in increasing the number of processes. Accordingly, it will be advantageous to use W film 45 instead of the third side-wall 21S, by forming W film 45 such that it has a thickness which does not fill the first trench formed between the first interlayer fins 16, and etching back it, as in this Example. Moreover, the lower electrode of capacitor may be connected directly on the plug of hybrid structure thus formed, as shown in FIG. 32.

Furthermore, the present invention includes the following embodiments.

A. A method for manufacturing a semiconductor device comprising:

co-installing a plurality of transistors, wherein the transistor has word lines extended in a first direction as a gate electrode, and is formed an active area intersecting with the first direction, and wherein two transistors sharing one diffusion layer form a cell unit;

forming a convex structure comprising a bit line connected to the diffusion layer shared by the cell unit and an insulation film covering the top and side of the bit line, wherein the structure is extended in a second direction intersecting with the first and third direction;

forming an opening after depositing a first insulation film on the entire surface, wherein the opening forms a first trench extended in the first direction of which the upper-width is broader than the lower-width, and exposes the convex structure, and the surfaces of diffusion layers adjacent within the two cell units;

depositing a first conductive material on the entire surface and etching back until at least the first insulating film constituting the wall surface of the first trench is exposed;

forming a first side wall on the side of the first insulation film exposed within the first trench and exposing a portion of the first conductive material by depositing a second insulation film on the first conductive material and etching back; and

separating the first conductive material in the first direction by etching using the first side wall as a mask,

wherein the first conductive material has a height lower than the surface of insulation film on the bit line, and forms a first contact plug which is connected to each of two diffusion layers adjacent within the first opening.

B. The method of A, wherein two transistors constituting the cell unit are formed by the following processes:

forming a plurality of isolating trenches on a semiconductor substrate, wherein these trenches are extended in the third direction;

forming element isolating areas by embedding an insulating material within the isolating trenches;

forming a diffusion layer by introducing an impurity into the surface of semiconductor substrate, wherein the surface is sandwiched between the element isolating areas;

forming a third insulation film on the semiconductor substrate;

forming a second plurality of trenches, wherein these trenches are passed through the third insulation film, extended in the first direction on the semiconductor substrate, shallower than the isolating trenches, and deeper than the diffusion layers;

forming word lines by embedding a second conductive material back from the upper side of the second trenches after forming insulation films on the surface of semiconductor substrate in the second trenches, and co-installing, in the third direction, a plurality of cell units comprising two transistors sharing one of diffusion layers isolated by the second trenches; and

embedding a forth insulation film within the second trenches on the word lines.

C. The method of B, wherein the convex structure extended in the second direction is formed by the following processes:

forming a third trenches to expose the surfaces of diffusion layers shared by the cell unit, wherein the trenches are extended in the first direction;

depositing a third conductive material and a fifth insulation film on the entire surface, and patterning thus lamination to be extended in the second direction to form bit lines, wherein the bit lines are connected to the diffusion layers within the third trenches; and

forming a second side wall comprising a sixth insulation film on the sides of the bit lines.

D. The method of C, wherein the first conductive material is subjected to an etch-back process until the surfaces of the fifth insulation films on the bit lines are exposed.

E. The method of C, wherein the first conductive material is subjected to an etch-back process such that the surfaces of the fifth insulation films on the bit lines are not exposed, and further comprising a process of depositing a seventh insulation film on the entire surface after separating the first conductive material in the first direction, and planarizing it until the surfaces of the fifth insulation films are exposed,

F. A method for manufacturing a semiconductor device comprising:

co-installing a plurality of transistors, wherein the transistor has word lines extended in a first direction as a gate electrode, and is formed an active area intersecting with the first direction, and wherein two transistors sharing one diffusion layer form a cell unit;

forming a convex structure comprising a bit line connected to the diffusion layer shared by the cell unit, an fifth insulation film covering the top of the bit line, and an sixth insulation film forming a second side wall at side of the bit line, wherein the structure is extended in a second direction intersecting with the first and third direction;

forming an opening after depositing a first insulation film on the entire surface, wherein the opening forms a first trench extended in the first direction of which the upper-width is broader than the lower-width, and exposes the convex structure, and the surfaces of diffusion layers adjacent within the two cell units;

forming a third side wall on the wall surface of the first trench and the side of the convex structure;

depositing a polysilicon film on the entire surface, and etching back until at least the fifth insulation film is exposed, wherein this film is also etched back by a desired depth from the top surface of the fifth insulation film;

forming a metal silicide film on the polysilicon film etched back, forming a barrier film on the metal silicide film and forming a metal film on the barrier film, wherein the thickness of the metal film does not fill the first trench;

exposing the barrier film by etching back the metal film, and separating in the first direction by etching back the barrier film, the metal silicide film and polysilicon film using the metal film as a mask; and

forming a seventh insulation film on the entire surface, and planarizing until the fifth insulation film is exposed, thereby a first contact plug which has a hybrid structure and is connected to the diffusion layer is formed.

G. The method of A-F, comprising a process for forming a capacitor connected electrically to the first contact plug.

H. The method of G, wherein the capacitor is connected directly to the first contact plug.

I. The method of G, wherein the capacitor is formed on a capacitor contact plug connected to the first contact plug.

J. The method of A-I, wherein the width of the surface of semiconductor substrate sandwiched between the element-isolating areas is approximately same as the width of the element-isolating area.

K. The method of A-J, wherein the separate-width of the lower side in the first contact plug is below the minimum feature size F.

What is claimed is:

1. A method for manufacturing a semiconductor device comprising:
forming a first trench on a semiconductor substrate, wherein the first trench has an upper side-width larger than an lower side-width, and is extended in a first direction;
forming an embedded layer within the first trench, wherein the embedded layer has a height lower than the top of the trench;
forming side-walls to cover wall surfaces of the first trench exposed on the embedded layer; and
etching the embedded layer by using the side-walls as a mask to separate the embedded layer into two in the direction parallel to a first direction.

2. The method according to claim 1, wherein the embedded layer comprises a conductive material.

3. The method according to claim 1, comprising a process of separating the embedded layer in a second direction which intersects with the first direction.

4. The method according to claim 3, wherein the process of separating the embedded layer into two directions comprises providing a compartment portion by which the first trench is separated into two directions, and forming the embedded layer within the first trench having compartment portion to separate the embedded layer into two directions at the bottom side of the first trench.

5. The method according to claim 4, wherein the embedded layer has the same height as the compartment portion, and the side-wall is formed on the embedded layer and the compartment portion.

6. The method according to claim 4, wherein the embedded layer is formed to cover the top surface of the compartment portion, and after separating the embedded layer in the first direction, the height of the embedded layer is reduced until the top surface of the compartment portion is exposed.

7. A semiconductor device comprising
an insulating material layer formed on a semiconductor substrate and
a plug of conductive material passing through the insulating material layer from its top side to its bottom side,
wherein the center positions of the top and bottom surfaces of the plug of conductive material are dislocated as viewed from the plane, and the plug of conductive material have substantially no bump in at least one side on a line extended in a misalignment direction.

8. The semiconductor device according to claim 7, wherein the top surface and bottom surface of the conductive material plug have a nearly rectangular shape.

9. The semiconductor device according to claim 7, wherein the top surface of the conductive material plug has an area larger than that of the bottom surface.

10. A semiconductor device comprising an insulating material layer formed on a semiconductor substrate and first and second plugs of conductive material passing through the insulating material layer from its top side to its bottom side, wherein the distance between the top surface-centers in the first and second plugs is larger than the distance between the bottom surface-centers.

11. The semiconductor device according to claim 10, wherein the top surface and bottom surface of the first and second conductive material plugs have a nearly rectangular shape.

12. The semiconductor device according to claim 10, wherein the top surfaces of the first and second conductive material plugs have an area larger than that of the bottom surfaces.

13. The semiconductor device according to claim 10, wherein the first and second conductive material plugs form a pair and a plurality of plug pairs are disposed in one direction.

14. The semiconductor device according to claim 13, wherein the space-width of the bottom surface of the plug pair is below the minimum feature size F value.

15. The semiconductor device according to claim 10, wherein the first and second conductive material plugs have a hybrid where a metal silicide layer and a metal plug are laminated on a polysilicon layer.

16. The semiconductor device according to claim 15, wherein the metal plug has a structure where a barrier film and a metal film are laminated, and the metal film is direct contact with an insulation layer at one side of the metal plug.

17. The semiconductor device according to claim 10, wherein the semiconductor device has 1 cell unit comprising two transistors sharing one diffusion layer on the semiconductor substrate, and the first and second conductive material plugs are connected to a diffusion layer which is not shared by two transistors of the cell unit.

18. The semiconductor device according to claim 17, comprising capacitors on the first and second conductive material plugs, each of which is electrically connected.

19. The semiconductor device according to claim 17, wherein the transistor has a conductor embedded within the semiconductor substrate as a gate electrode.

20. The semiconductor device according to claim 19, comprising a bit line connected by the diffusion layer shared by two transistors of the cell unit, wherein one side of the conductive material plug is defined by a side-wall insulation film formed on the side-wall of the bit line.
